(19) United States
(12) Patent Application Publication
(10) Pub. No.: US 2025/0118693 A1
(43) Pub. Date: Apr. 10, 2025

(54) TECHNIQUES FOR SEMICONDUCTOR DIE COUPLING IN STACKED MEMORY ARCHITECTURES

(71) Applicant: Micron Technology, Inc., Boise, ID (US)

(72) Inventors: Bharat Bhushan, Boise, ID (US); Kunal R. Parekh, Boise, ID (US); Akshay N. Singh, Boise, ID (US)

(21) Appl. No.: 18/776,197

(22) Filed: Jul. 17, 2024

Related U.S. Application Data
(60) Provisional application No. 63/588,642, filed on Oct. 6, 2023.

(51) Int. Cl. H01L 23/00; H01L 21/768; H01L 23/498; H01L 25/18; H10B 80/00

(52) U.S. Cl. CPC H01L 24/08; H01L 21/76877; H01L 23/49822; H01L 24/80; H01L 21/76807; H01L 25/18; H01L 2224/08145; H01L 2224/08225; H01L 2224/80895; H01L 2224/80896; H01L 2924/1431; H01L 2924/1436; H10B 80/00

(57) ABSTRACT

Methods, systems, and devices for techniques for semiconductor die coupling in stacked memory architectures are described. A semiconductor system may include a semiconductor unit formed by multiple semiconductor dies, where each semiconductor die may be fabricated to be individually separable. Each semiconductor die may include a respective portion of circuitry associated with the semiconductor unit. The multiple semiconductor dies may be coupled with a carrier, and each semiconductor die may be coupled (e.g., electrically, communicatively) with at least one other semiconductor die. At least some of the semiconductor dies may be coupled with a respective set of one or more memory arrays, where each memory array may be operable based on the coupling between the multiple semiconductor dies.

### CROSS REFERENCE

The present Application for Patent claims priority to U.S. Patent Application No. 63/588,642 by Bhushan et al., entitled “TECHNIQUES FOR SEMICONDUCTOR DIE COUPLING IN STACKED MEMORY ARCHITECTURES,” filed Oct. 6, 2023, which is assigned to the assignee hereof, and which is expressly incorporated by reference in its entirety herein.

### TECHNICAL FIELD

The following relates to one or more systems for memory, including techniques for semiconductor die coupling in stacked memory architectures.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells in a non-volatile configuration may maintain stored logic states for extended periods of time even in the absence of an external power source. Memory cells in a volatile configuration may lose stored states when disconnected from an external power source.

### BRIEF DESCRIPTION OF THE DRAWINGS

FIG. 1 shows an example of a system that supports techniques for semiconductor die coupling in stacked memory architectures in accordance with examples as disclosed herein.

FIG. 2 shows an example of a system that supports techniques for semiconductor die coupling in stacked memory architectures in accordance with examples as disclosed herein.

FIG. 3 shows an example of an interface architecture that supports techniques for semiconductor die coupling in stacked memory architectures in accordance with examples as disclosed herein.

FIGS. 4A and 4B show examples of semiconductor components and die assemblies that support techniques for semiconductor die coupling in stacked memory architectures in accordance with examples as disclosed herein.

FIGS. 5 through 12 illustrate examples of operations for forming a semiconductor system utilizing techniques for semiconductor die coupling in stacked memory architectures in accordance with examples as disclosed herein.

FIGS. 13 and 14 show flowcharts illustrating a method or methods that support techniques for semiconductor die coupling in stacked memory architectures in accordance with examples as disclosed herein.

### DETAILED DESCRIPTION

Some memory systems may include a stack of semiconductor dies, including one or more memory dies (e.g., array dies) or one or more stacks of stacked memory dies that are stacked with a logic die that is operable to access a set of memory arrays distributed across the one or more memory dies. Such a stacked architecture may be implemented as part of a high bandwidth memory (HBM) system or a tightly-coupled dynamic random access memory (TCDRAM) system, and may support solutions for memory-centric logic, such as graphics processing units (GPUs), among other implementations. In some examples, an HBM system may include a stack of memory dies located (e.g., positioned, placed) above a logic die. In some examples, a TCDRAM system may be closely coupled (e.g., physically coupled, electrically coupled, directly coupled) with a processor, such as a GPU or other host, as part of a physical memory map accessible to the processor. Such coupling may include one or more processors being implemented in a same semiconductor die as at least a portion of an HBM system or a TCDRAM system (e.g., as part of a logic die), or one or more processors being implemented in a die that is directly coupled (e.g., fused) with another die that includes at least a portion of an HBM system or a TCDRAM system, or otherwise coupled with another die that includes at least a portion of an HBM system or a TCDRAM system (e.g., via a silicon interposer or other intervening component). Unlike cache-based memory, a TCDRAM system may not be backed by a level of external memory with the same physical addresses. For example, a TCDRAM system may be associated with and located within a dedicated base address, where each portion of the TCDRAM system may be non-overlapping within the address.

Some semiconductor dies (e.g., a logic die) may include multiple components such as interface blocks (e.g., memory interface blocks, interface circuitry), logic blocks, controllers, processors, and other components. In some examples, such dies may be associated with a relatively low manufacturing yield, which may be associated with a relative size or complexity of integrating multiple components on a same die. For instance, a die may be rejected (e.g., discarded) during a manufacturing process if at least one of the components of the die fails an evaluation procedure. That is, although a majority of components of the die may satisfy an evaluation, a single failed component may cause the die to be rejected. Accordingly, a likelihood that each component of a relatively complex or relatively large die satisfies an evaluation may be relatively low, thus resulting in relatively low yield of such dies.

In accordance with examples as disclosed herein, a semiconductor component (e.g., a semiconductor unit, a semiconductor subsystem, a logic unit, a logic portion of an HBM system, a logic portion of a TCDRAM system, a heterogeneous semiconductor device) may be formed with multiple semiconductor die portions (e.g., relatively smaller dies, dies each including a respective subset of components of a logic unit) that are bonded with a carrier and interconnected with each other. At least some, if not all of the die portions may individually satisfy an evaluation (e.g., may be known good dies (KGDs) before interconnection). In some examples, the die portions may be referred to as “chiplets” (e.g., logic chiplets), and each chiplet may include a respective portion of circuitry that may be otherwise associated with functionality of a relatively larger die. For example, such a semiconductor component may be formed with a first chiplet including memory interface circuitry, a second chiplet including processor circuitry, a third chiplet including logic circuitry, among other examples of subdivisions of circuitry. Multiple chiplets may be interconnected with conductive paths (e.g., in a redistribution layer (RDL), via a backside of at least some of the chiplets) and with one or more through silicon vias (TSVs) in each of the chiplets, which may involve various semiconductor fabrication techniques of the bonded chiplets. At least some of the chiplets may be further coupled with one or more memory dies (e.g., stacked memory dies). In some implementations, one or more stacked memory dies may have dedicated conductive paths (e.g., for a power distribution network (PDN), using through reconstruction vias (TRVs)) for power delivery or other signals that bypass the chiplets (e.g., bypassing one or more dies of a logic layer).

By supporting a subdivision and coupling of multiple chiplets (e.g., that make up a multiple-die semiconductor unit), relatively smaller portions of a wafer may be rejected (e.g., based on rejecting failed chiplets), which may support an increased yield for the wafer. Accordingly, a manufacturing yield for a multiple-die semiconductor unit (e.g., a logic unit) may be improved compared to a yield for a single-die semiconductor unit (e.g., based on an increased yield of interconnecting relatively smaller KGD chiplets). Additionally, dedicated conductive paths (e.g., for power delivery to the one or more memory dies) may be associated with lower resistance, and may not occupy area in a substrate of other dies (e.g., of a single-die logic system), which may support increased area for semiconductor circuitry, increased wafer circuitry yield, and improved performance of a memory system.

In addition to applicability in systems as described herein, techniques for semiconductor die coupling in stacked memory architectures may be generally implemented to support artificial intelligence or machine learning applications, among other types of computationally-intensive applications. As the use of artificial intelligence increases to support machine learning, analytics, decision making, or other related applications, electronic devices that support artificial intelligence applications and processes may be desired. For example, artificial intelligence applications may be associated with accessing relatively large quantities of data for analytical purposes and may benefit from memory systems capable of effectively and efficiently storing relatively large quantities of data or accessing stored data relatively quickly. Implementing the techniques described herein may support artificial intelligence and machine learning techniques by supporting higher device yield and interconnectivity, including by forming semiconductor units (e.g., logic dies in an HBM system, logic dies in a TCDRAM system) from relatively smaller semiconductor die portions (e.g., rather than as a single monolithic unit). Such techniques may allow relatively smaller components to be rejected, and remaining smaller components to be accepted, which may improve manufacturing yield of devices that support artificial intelligence and machine learning techniques. Additionally, yield of such devices may be improved based on the dedicated vias for power delivery to memory arrays (e.g., instead of delivering power through circuitry of other dies), which may support increased circuit density of a wafer. Moreover, the techniques herein may improve power efficiency of memory arrays (e.g., of a tightly-coupled stack of array dies), supporting increased performance and reduced latency of stacked memory architectures.

Features of the disclosure are illustrated and described in the context of systems and dies. Features of the disclosure are further illustrated and described in the context of interface architectures, semiconductor components, die assemblies, illustrative fabrication techniques, and flowcharts.

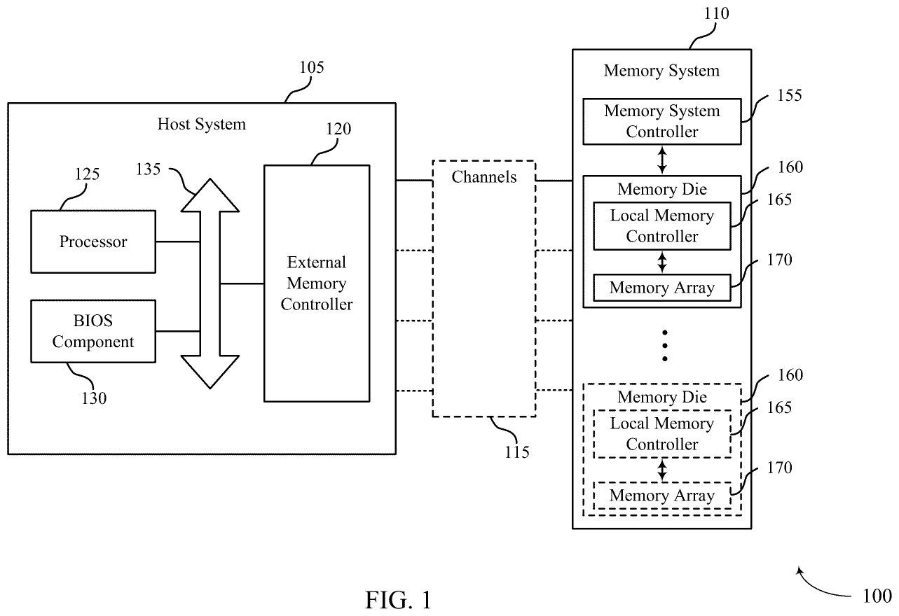

FIG. 1 shows an example of a system 100 that supports techniques for semiconductor die coupling in stacked memory architectures in accordance with examples as disclosed herein. The system 100 may include portions of an electronic device, such as a computing device, a mobile computing device, a wireless communications device, a graphics processing device, a vehicle, or other systems. The system 100 includes a host system 105, a memory system 110, and one or more channels 115 coupling the host system 105 with the memory system 110 (e.g., to provide a communicative coupling). The system 100 may include one or more memory systems 110, but aspects of the one or more memory systems 110 may be described in the context of a single memory system 110.

The host system 105 may be an example of a processing system (e.g., circuitry, one or more processors, an application processing system, processing circuitry, one or more processing components) that uses memory to execute processes (e.g., applications, functions, computations), such as a processing system of a computing device, a mobile computing device, a wireless communications device, a graphics processing device, a wearable device, an internet-connected device, a vehicle controller, a system on a chip (SoC), or other stationary or portable electronic device, among other examples. The host system 105 may include one or more of an external memory controller 120, a processor 125, a basic input/output system (BIOS) component 130, or other components (e.g., a peripheral component, an input/output controller, not shown). The components of the host system 105 may be coupled with one another using a bus 135.

An external memory controller 120 may be configured to enable communication of information (e.g., data, commands, control information, configuration information) between components of the system 100 (e.g., between components of the host system 105, such as the processor 125, and the memory system 110). For example, an external memory controller 120 may generate commands (e.g., in response to or to otherwise support an application of the host system 105) to write data to a memory system 110, or to read data from the memory system 110, or to otherwise communicate with a memory system 110. An external memory controller 120 may process (e.g., convert, translate) communications exchanged between the host system 105 and the memory system 110. In some examples, an external memory controller 120, or other component of the system 100, or associated functions described herein, may be implemented by or be part of the processor 125. For example, an external memory controller 120 may be hardware, firmware, or software (e.g., instructions), or some combination thereof implemented by a processor 125 or other component of the system 100 or the host system 105. Although an external memory controller 120 is illustrated outside the memory system 110, in some examples, an external memory controller 120, or its functions described herein, may be implemented by one or more components of a memory system 110 (e.g., a memory system controller 155, a local memory controller 165) or vice versa. In various examples, the host system 105 or an external memory controller 120 may be referred to as a host.

A processor 125 may be operable to provide functionality (e.g., control functionality, processing functionality) for the system 100 or the host system 105. A processor 125 may be a general-purpose processor, a digital signal processor (DSP), an application-specific integrated circuit (ASIC), a field-programmable gate array (FPGA) or other programmable logic device, discrete gate or transistor logic, discrete hardware components, or any combination thereof (e.g., as one or more processing components that are configured individually or collectively to support an application of the host system 105). In some examples, a processor 125 may be an example of a central processing unit (CPU), a graphics processing unit (GPU), a general-purpose GPU (GPGPU), or an SoC, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The memory system 110 may be a component of the system 100 that is operable to provide physical memory locations (e.g., addresses) that may be used or referenced by the system 100 (e.g., by the host system 105). The memory system 110 may include a memory system controller 155 and one or more memory dies 160 (e.g., memory chips) to support a capacity for data storage. The memory system 110 may be configurable to work with one or more different types of host systems 105, and may respond to and execute commands provided by the host system 105 (e.g., via an external memory controller 120). For example, the memory system 110 (e.g., a memory system controller 155) may receive a write command indicating that the memory system 110 is to store data received from the host system 105, or receive a read command indicating that the memory system 110 is to provide data stored in a memory die 160 to the host system 105, or receive a refresh command indicating that the memory system 110 is to refresh data stored in a memory die 160, among other types of commands and operations.

A memory system controller 155 may include components (e.g., circuitry, logic, instructions) operable to control operations of the memory system 110. A memory system controller 155 may include hardware, firmware, or instructions that enable the memory system 110 to perform various operations, and may be operable to receive, transmit, or execute commands, data, or control information related to operations of the memory system 110. A memory system controller 155 may be operable to communicate with one or more of an external memory controller 120, one or more memory dies 160, or a processor 125. In some examples, a memory system controller 155 may control operations of the memory system 110 in cooperation with a local memory controller 165 of a memory die 160.

Each memory die 160 may include one or more local memory controllers 165 and one or more memory arrays 170. A memory array 170 may be a collection of memory cells, with each memory cell being operable to store one or more bits of data. A memory array 170 may include a two-dimensional (2D) array of memory cells, or a three-dimensional (3D) array of memory cells. In some examples, a two-dimensional (2D) memory die 160 may include a single memory array 170. In some examples, a three-dimensional (3D) memory die 160 may include two or more memory arrays 170, which may be stacked or positioned beside one another (e.g., relative to a substrate).

A local memory controller 165 may include components (e.g., circuitry, logic, instructions) operable to control operations of a memory die 160. In some examples, a local memory controller 165 may be operable to communicate (e.g., receive or transmit data or commands or both) with a memory system controller 155. In some examples, a memory system 110 may not include a memory system controller 155, and a local memory controller 165 or an external memory controller 120 may perform various functions described herein. As such, a local memory controller 165 may be operable to communicate with a memory system controller 155, with other local memory controllers 165, or directly with an external memory controller 120, or a processor 125, or any combination thereof. Examples of components that may be included in a memory system controller 155 or a local memory controller 165 or both may include receivers for receiving signals (e.g., from the external memory controller 120), transmitters for transmitting signals (e.g., to the external memory controller 120), decoders for decoding or demodulating received signals, encoders for encoding or modulating signals to be transmitted, sense components for sensing states of memory cells of a memory array 170, write components for writing states to memory cells of a memory array 170, or various other components operable for supporting described operations of a memory system 110.

A host system 105 (e.g., an external memory controller 120) and a memory system 110 (e.g., a memory system controller 155) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, an electrically conductive path) between terminals associated with the components of the system 100. For example, a channel 115 may be associated with a first terminal (e.g., including one or more pins, including one or more pads) at the host system 105 and a second terminal at the memory system 110. A terminal may be an example of a conductive input or output point of a device of the system 100, and a terminal may be operable to act as part of a channel 115. In some implementations, at least the channels 115 between a host system 105 and a memory system 110 may include or be referred to as a host interface (e.g., a physical host interface). In some implementations, a host interface may include or be associated with interface circuitry (e.g., signal drivers, signal latches) at the host system 105 (e.g., at an external memory controller 120), or at the memory system 110 (e.g., at a memory system controller 155), or both.

In some examples, a channel 115 (e.g., associated signal paths and terminals) may be dedicated to communicating one or more types of information. For example, the channels 115 may include one or more command and address channels, one or more clock signal channels, one or more data channels, among other channels or combinations thereof. In some examples, signaling may be communicated via the channels 115 using single data rate (SDR) signaling or double data rate (DDR) signaling. In SDR signaling, one modulation symbol (e.g., signal level) of a signal may be registered for each clock cycle (e.g., on a rising or falling edge of a clock signal). In DDR signaling, two modulation symbols of a signal may be registered for each clock cycle (e.g., on both a rising edge and a falling edge of a clock signal).

In some examples, at least a portion of the system 100 may implement a stacked die architecture in which multiple semiconductor dies are physically and communicatively coupled. In some such implementations, circuitry for accessing one or more memory arrays 170 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, that are each configured to access one or more memory arrays of the second dies. In some examples, the system may include a controller (e.g., a memory controller, an interface controller, a host interface controller, at least a portion of an external memory controller 120) for each set of one or more first interface blocks to support access operations (e.g., to access one or more memory arrays 170) via the set of first interface blocks. In some examples, such controllers may be located in the same first die as the first interface blocks.

In some examples, multiple semiconductor dies of a memory system 110 or of a system 100 (e.g., an HBM system including aspects of a memory system 110, a TCDRAM system including aspects of a memory system 110 and a host system 105) may include one or more array dies (e.g., memory dies 160) stacked with a logic die (e.g., that includes aspects of the host system 105, that is coupled with another die or other component that includes the host system 105) that includes interface blocks operable to access a set of memory arrays 170 distributed across the one or more second dies. A system 100 or portion thereof having a stacked memory architecture may support techniques for semiconductor die coupling in stacked memory architectures. For instance, a semiconductor unit (e.g., a semiconductor component, a logic unit) may be formed with multiple semiconductor die portions (e.g., chiplets, logic chiplets) that are interconnected after an evaluation procedure (e.g., as an interconnection of logic chiplets, such as KGDs, that satisfy the evaluation). At least some of the chiplets may be further coupled with one or more stacked memory arrays 170, which also may have dedicated vias for power delivery (e.g., PDN through-vias (TVs), TRVs). Thus, a manufacturing yield of a memory system 110 or a system 100 (e.g., an HBM system, a TCDRAM system) may be improved based on forming semiconductor units with multiple semiconductor chiplets and the dedicated vias, and the memory system 110 may have improved power efficiency based on delivering power to the one or more stacked memory arrays 170 via one or more dedicated vias.

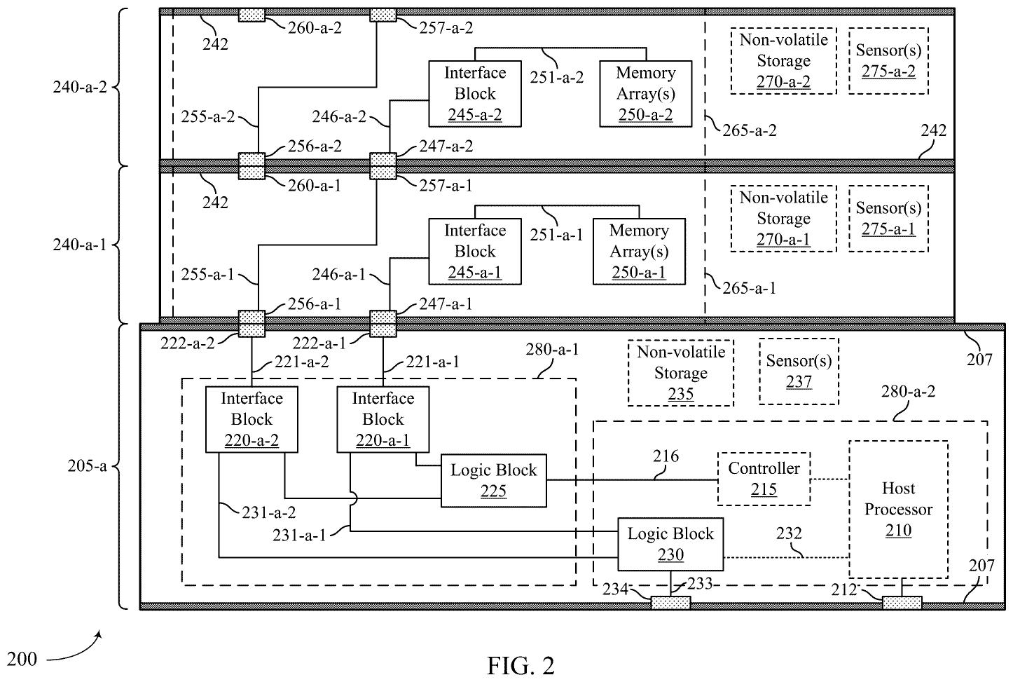

FIG. 2 shows an example of a system 200 (e.g., a semiconductor system, a system of coupled semiconductor dies, an HBM system, a TCDRAM system) that supports techniques for semiconductor die coupling in stacked memory architectures in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 170, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., TCDRAM implementations), a die 205 may include a host processor 210. A host processor 210 may be an example of a host system 105, or a portion thereof (e.g., a processor 125, aspects of an external memory controller 120, or both). The host processor 210 may be configured to perform operations that implement storage of the memory arrays 250 (e.g., to support an application or other function of a host system 105, which may request access of the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115 described with reference to FIG. 1. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of an external memory controller 120, or of a memory system controller 155, or a combination thereof. For example, the controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-1. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth memory configuration of the system 200, in accordance with a tightly-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220. The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 (e.g., via a bus, via a contact 212 for a host processor 210 external to a die 205) such that the logic block 230 may support an interface between the host processor 210 and the logic blocks 225 or interface blocks 220. For example, a host processor 210 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210. Additionally, or alternatively, a logic block 230 may communicate with a host processor 210, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

Each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the dic 240-a-2 via a bus 255-a-1 of the dic 240-a-1, which may bypass interface blocks 245 of the die 240-a-1. Such techniques may be extended for interconnection among more than two dies 240 (e.g., for interconnection via a respective bus 255 of multiple dies 240).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the dic 240-a-1, the bus 255-a-1 may be coupled with the bus 246-a-2 via a contact 257-a-1 of the dic 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the dic 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205 with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) of the die 205 or dies 240, among other materials that may support such fusion. However, coupling among dies 205 and dies 240 may be implemented in accordance with other techniques, which may implement solder, adhesives, thermal interface materials, and other intervening materials.

In some examples, dies 240 may be coupled in a stack (e.g., forming a “cube” or other arrangement of dies 240), and one or more of such stacks may subsequently be coupled with a dic 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 155, a local memory controller 165, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 155. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each dic 240 of the system 200 is illustrated with a single unit 265 (e.g., unit 265-a-1 of dic 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In accordance with examples disclosed herein, functionality of a die 205 may be implemented as a semiconductor unit (e.g., a semiconductor system) that is formed with multiple semiconductor die portions (e.g., semiconductor chiplets, relatively smaller semiconductor dies, KGDs), where each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof. Although non-limiting examples of units 280 are shown, each unit 280 may include any combination of components of a die 205, or other components. For example, a unit 280-a-1 may additionally include a logic block 230, or a logic block 225 may be included in a different unit 280 (e.g., of another chiplet, in a divided HBM or TCDRAM implementation). In some examples, a respective set of one or more dies 240 may be stacked on a corresponding die portion (e.g., a die portion having one or more units 280-a-1), and the corresponding die portion may include circuitry to operate (e.g., control) the respective set of one or more dies 240 (e.g., a unit 280-a-1 may correspond to one or more units 265 of each die 240 in the respective set).

In accordance with techniques herein, a first die portion and a second die portion may be separately formed (e.g., may have separate substrates, may be cut from different wafers) and may be coupled (e.g., electrically, functionally) with one another during a manufacturing process (e.g., in accordance with semiconductor manufacturing techniques, after establishing die portions as KGDs) as part of forming a semiconductor unit (e.g., rather than forming a die 205 as a single monolithic unit from a wafer). In some examples, the first die portion may be coupled with the second die portion via one or more conductive signal paths, where the conductive signal paths may be included in one or more conductive layers of an RDL (e.g., over the first die portion and second die portion). The one or more conductive paths may be examples of or include the host interface 216, buses 231, buses 232, buses 233, or other conductive signal paths described herein. In some examples, the one or more conductive paths may be formed concurrently with one or more other conductors (e.g., TSVs, PDN TRVs) along multiple (e.g., two, three, or more) different depths as part of a manufacturing process for a semiconductor unit, such as in a double damascene operation, a triple damascene operation, or a combination thereof.

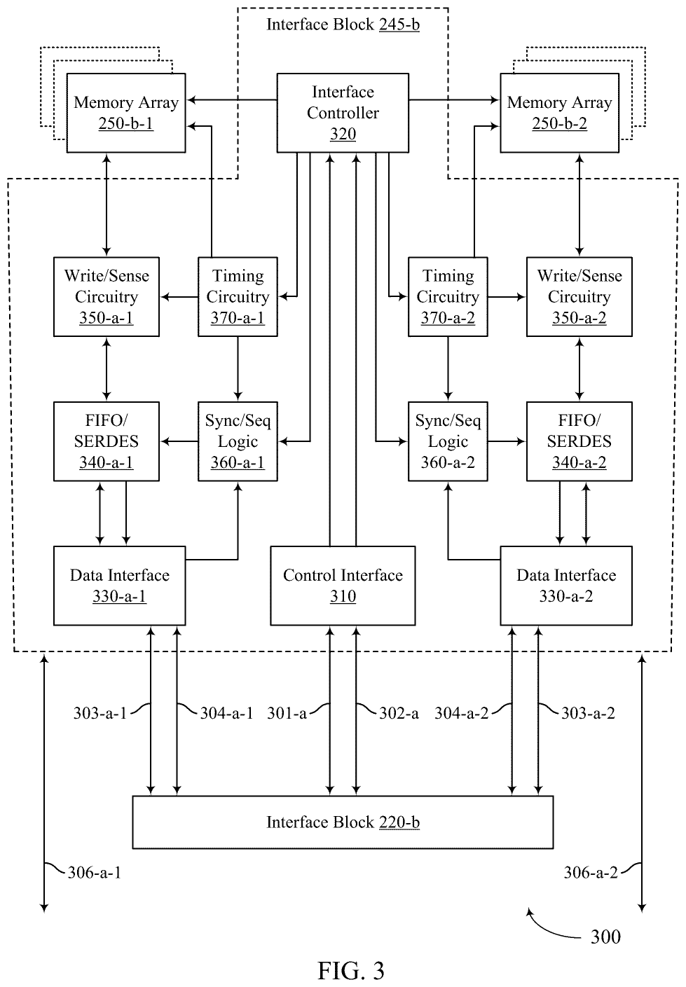

FIG. 3 shows an example of an interface architecture 300 that supports techniques for semiconductor die coupling in stacked memory architectures in accordance with examples as disclosed herein. The interface architecture 300 illustrates an example of an interface block 245-b (e.g., of a die 240) coupled with an interface block 220-b (e.g., of a die 205). The interface block 245-b may be communicatively coupled with the interface block 220-b via one or more of a bus 301, a bus 302, a bus 303, and a bus 304, each of which may be examples of one or more signal paths of a bus 221 and a bus 246, as well as a bus 255, where applicable. The interface block 245-b may further be coupled with one or more buses 306 (e.g., power delivery buses, PDN TRVs, communicative buses), which may deliver power directly to components of the interface block 245-b or memory arrays 250-b (e.g., or some other component of a die 240).

The interface block 245-b includes a control interface 310 (e.g., a command interface), which may be configured to communicate signaling with the interface block 220-b. For example, the control interface 310 may include circuitry (e.g., a receiver, one or more latches) configured to receive control signaling (e.g., modulated control signaling, access command signaling, configuration signaling, address signaling, such as row address signaling or column address signaling) via the bus 301-a. The control interface 310 also may include circuitry configured to receive clock signaling (e.g., clock signaling associated with the control interface 310, clock signaling having one or more phases, such as true and complement phases, dk_t/c signaling from the interface block 220-b) via the bus 302-a, which the control interface 310 may use for receiving the control signaling of the bus 301-a (e.g., for triggering the one or more latches). The control interface 310 may transmit (e.g., forward) the control signaling and the clock signaling (e.g., for timing of other operations of the interface block 245-b) to an interface controller 320.

The interface block 245-b also includes two data interfaces 330 (e.g., data interfaces 330-a-1 and 330-a-2), which also may be configured to communicate signaling with the interface block 220-b. Each data interface 330 may include corresponding buses and circuitry, the operation of which may be associated with (e.g., controlled by, coordinated with, operated based on) control signaling via the control interface 310. Although the example of interface block 245-b includes two data interfaces 330 associated with the control interface 310 (e.g., in a “channel pair” arrangement, in a “pseudo-channel pair” arrangement), the described techniques for an interface block 245 may include any quantity of one or more data interfaces 330, and associated buses and circuitry, for a given control interface 310 of the interface block 245.

Each data interface 330 may be associated with respective data path circuitry, which may include respective first-in-first-out (FIFO) and serialization/deserialization (SERDES) circuitry (e.g., FIFO/SERDES 340), respective write/sense circuitry 350, respective synchronization and sequencing circuitry (e.g., sync/seq logic 360), and respective timing circuitry 370, along with interconnecting signal paths (e.g., one or more buses). However, in some other examples, data path circuitry may be arranged in a different manner, or may include different circuitry components, which may include circuitry that is dedicated to respective data paths, or shared among data paths, or various combinations thereof. Each data interface 330 also may be associated with a respective set of one or more memory arrays 250. In some examples, each memory array 250 may be understood to include respective addressing circuitry such as bank logic or decoders (e.g., a row decoder, a column decoder), or memory cell sense amplifier circuitry, among other array circuitry. However, in some other examples, at least a portion of such circuitry may be included in an interface block 245.

Each data interface 330 may include circuitry (e.g., one or more latches, one or more drivers) configured to communicate (e.g., receive, transmit) data signaling (e.g., modulated data signaling, DQ signaling) via a respective bus 303. Each data interface 330 also may include circuitry to communicate clock signaling via a respective bus 304, which may support clock signal reception by the data interface 330 (e.g., first clock signaling associated with the data interface 330, clock signaling having one or more phases, such as true and complement phases, DQS_t/c signaling from the interface block 220-b, clock signaling associated with data reception or write operations), or clock signal transmission by the data interface 330 (e.g., second clock signaling associated with the data interface 330, RDQS_t/c signaling to the interface block 220-b, clock signaling associated with data transmission or read operations), or both. In some examples, a data interface 330, a bus 303, or a combination of a bus 303 and a bus 304, may be associated with a “pseudo-channel,” and multiple pseudo-channels may be associated with the same control interface 310 or the same control bus (e.g., a bus 301, a combination of a bus 301 and a bus 302). In some implementations, pseudo-channels of multiple interface blocks 245 may be grouped together (e.g., functionally, logically, electrically, such as through hard-wired signal paths or multiplexing circuitry) to support a channel set (e.g., associated with a corresponding host interface 216). Each data interface 330 may transmit clock signaling (e.g., received clock signaling, DQS_t/c signaling) to sync/seq logic 360 via a respective bus (e.g., for timing of other operations of the interface block 245-b).

The interface controller 320 may support various functionality (e.g., control functionality, configuration functionality) of the interface block 245-b for accessing or otherwise managing operations of the coupled memory arrays 250. For example, the interface controller 320 may support access command coordination or configuration, latency or timing compensation, access command buffering (e.g., in accordance with a FIFO or other organizational scheme), mode registers or logic for configuration settings, or test functionality (e.g., evaluation functionality, BIST functionality), among other functions or combinations thereof. For each data path of the interface block 245 (e.g., associated with a respective data interface 330), the interface controller 320 may be configured to transmit signaling (e.g., address signaling, such as row address or row activation signaling) to the respective memory arrays 250 via a bus. For each data path of the interface block 245, the interface controller 320 may communicate signaling (e.g., timing signaling, which may be based on clock signaling received from the control interface 310, configuration signaling) with respective timing circuitry 370 and sync/seq logic 360 via respective buses.

For each data path, the respective timing circuitry 370 may support timing of various operations (e.g., activations, coupling operations, signal latching, signal driving) relative to timing signaling received from the interface controller 320. For example, timing circuitry 370 may include a timing chain (e.g., a global column timing chain) configured to generate one or more clock signals or other initiation signals for controlling operations of the respective data path, and such signaling may include transitions (e.g., rising edge transitions, falling edge transitions, on/off transitions) that are offset from, at a different rate from, or otherwise different from transitions of signaling from the interface controller 320 to support a given operation or combination of operations. For example, timing circuitry 370 may be configured to transmit signaling (e.g., address signaling, such as column address or column activation signaling) to the respective memory arrays 250, to transmit signaling to the respective write/sense circuitry 350 (e.g., latch or driver timing signaling), and to transmit signaling to the respective sync/seq logic (e.g., timing signaling).

For each data path, the respective FIFO/SERDES 340 may be configured to convert between data signaling of a first bus width (e.g., a relatively wide bus width, a data read/write (DRW) bus, a bus for communications with write/sense circuitry 350 having a relatively larger quantity of signal paths) and a second bus width (e.g., a relatively narrow bus width, a bus for communications with a data interface 330 having a relatively smaller quantity of signal paths). In some examples, such a conversion may be accompanied by changing a rate of signaling between signaling from the data interface 330 and the write/sense circuitry 350 (e.g., to maintain a given throughput). In various examples, the FIFO/SERDES 340 may receive data signaling from the data interface 330 and transmit data signaling to the write/sense circuitry 350 (e.g., to support a write operation), or may receive data signaling from the sense circuitry 350 and transmit data signaling to the data interface 330 (e.g., to support a read operation). In some examples (e.g., to support a read operation), the FIFO/SERDES 340 may be configured to transmit clock signaling (e.g., RDQS_t/c signaling) to the data interface 330, which may be forwarded to the interface block 220-b.

The timing or other synchronization of operations performed by the FIFO/SERDES 340 may be supported by one or more clock signals, among other signaling, received from the respective sync/seq logic 360. For example, the sync/seq logic 360 may generate or otherwise coordinate clock signaling to support the different rates of signaling of different buses (e.g., based on received clock signaling). Additionally, or alternatively, the FIFO/SERDES 340 may operate in a direction (e.g., for data transmission to a data interface 330, for data reception from a data interface 330) or other mode based on configuration signaling received from the sync/seq logic 360.

For each data path, the respective write/sense circuitry 350 may be configured to support the accessing (e.g., data signaling, write signaling, read signaling) of the respective set of one or more memory arrays 250. For example, the write/sense circuitry 350 may be coupled with the memory arrays 250 via a bus (e.g., a global input/output (GIO) bus), which may include respective signal paths associated with each memory array 250, or may include signal paths that are shared for all of the memory arrays 250 of the set, in which case the memory array circuitry may include multiplexing circuitry operable to couple the bus with a selected one of the memory arrays 250. In some examples, a bus between the write/sense circuitry 350 and the set of one or more memory arrays 250 may include a same quantity of signal paths as a bus between the write/sense circuitry 350 and the FIFO/SERDES 340 (e.g., for signaling GIO [287:0]) or a same quantity of signal paths as a quantity of columns in each memory array 250. In some other examples, the memory arrays 250 may include a quantity of columns that is an integer multiple of the quantity of signal paths of the bus, in which case the memory array circuitry (e.g., each memory array 250) may include decoding circuitry operable to couple a subset of columns of memory cells, or associated circuitry, with the bus.

To support write operations, the write/sense circuitry 350 may be configured to drive signaling that is operable to write one or more logic states to memory cells of the memory arrays 250 (e.g., based on received data, based on received timing signaling, based on data signaling received via a bus 303 and on control signaling received via a bus 301-a). In some examples, such signaling may be transmitted to supporting circuitry of or otherwise associated with the memory arrays 250 (e.g., as an output of signals corresponding to logic states to be written), such as sense amplifier circuitry, voltage sources, current sources, or other driver circuitry operable to apply a bias across a storage element of the memory cells (e.g., across a capacitor, across a ferroelectric capacitor), or apply a charge, a current, or other signaling to a storage element of the memory cells (e.g., to apply a current to a chalcogenide or other configurable memory material, to apply a charge to a gate of a NAND memory cell), among other examples.

To support read operations, the write/sense circuitry 350 may be configured to receive signaling that the write/sense circuitry 350 may further amplify for communication through the interface block 245-b. For example, the write/sense circuitry 350 may be configured to receive signaling corresponding to logic states read from the memory arrays 250, but at a relatively low driver strength (e.g., relatively ‘analog’ signaling, which may be associated with a relatively low drive strength of sense amplifiers of the memory arrays 250). The write/sense circuitry 350 may thus include further sense amplification (e.g., a data sense amplifier (DSA) between signal paths between the write/sense circuitry and the set of one or more memory arrays and respective signal paths between the write/sense circuitry and the FIFO/SERDES), which each may have a relatively high drive strength (e.g., for driving relatively ‘digital’ signaling).

The features of the interface architecture 300 may be duplicated in various quantities and arrangements to support a semiconductor system having multiple dies, such as various examples of a system 200. In an example implementation, each die 240 may be configured with 64 instances of the interface block 245-b, which may support a data signaling width of 9,216 signal paths for each die 240 (e.g., where each bus 303 of a channel pair is associated with 72 signal paths). For a system 200 having a stack of eight dies 240 coupled with a die 205, the die 205 may thus be configured with 512 instances of the interface block 220-b, thereby supporting an overall data signaling width of 73,738 signal paths for the system 200. However, in other implementations, dies 205 and dies 240 may be configured with different quantities of interface blocks 220 and 245, respectively, and a system 200 may be configured with different quantities of dies 240 per die 205.

In accordance with techniques herein, a semiconductor unit (e.g., a logic unit, a semiconductor assembly) may be formed with multiple relatively smaller semiconductor dies (e.g., chiplets, logic chiplets). A relatively smaller semiconductor die may include one or more interface blocks 220-b. Accordingly, a set of memory dies (e.g., array dies) that are stacked on the die portion may include one or more interface blocks 245-b with multiple memory arrays 250-b. In some examples, each of the bus 301-a, the bus 302-a, the buses 303, and the buses 304 may include or be examples of TSVs, bonding pads, conductive paths, or other mechanisms that support a coupling between a die portion and the set of memory dies (e.g., between logic chiplets and stacks of memory dies). Further, one or more buses 306 (e.g., PDN TRVs) may bypass an interface block 220-b (e.g., may bypass the die portions), which may enable power delivery to a set of memory dies with increased efficiency (e.g., as compared to delivering power via the interface block 220-b or other components of a logic die).

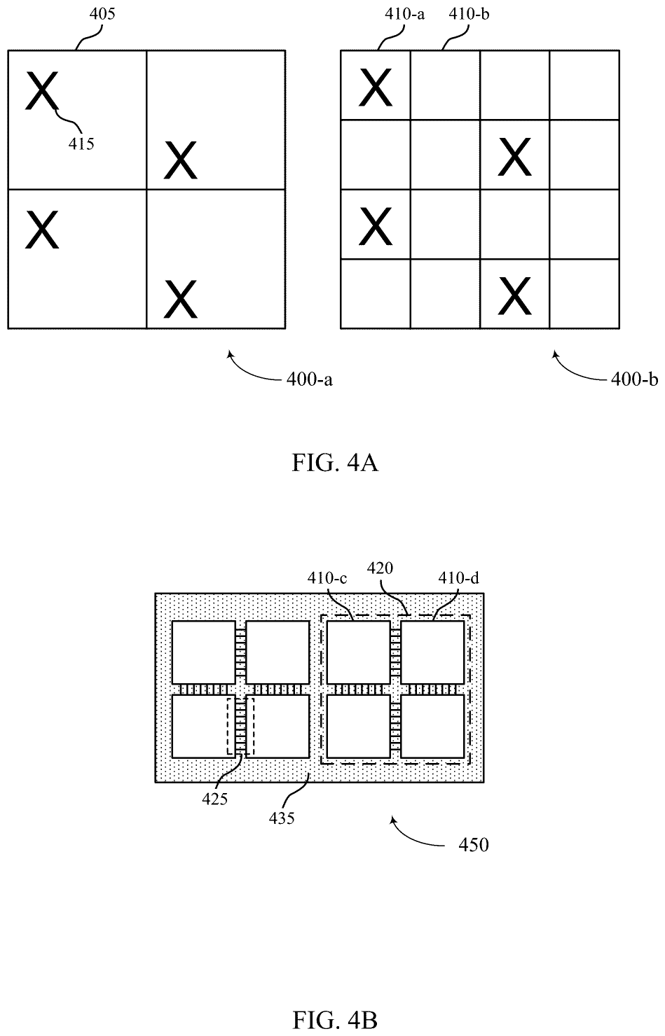

FIGS. 4A and 4B show examples of semiconductor components 400 and a die assembly 450 that support techniques for semiconductor die coupling in stacked memory architectures in accordance with examples as disclosed herein. In FIG. 4A, a semiconductor component 400-a (e.g., a wafer, a die group) may include multiple dies 405 (e.g., logic dies), each of which may include multiple components (e.g., subcomponents). For instance, a die 405 may include multiple portions of circuitry such as interface circuitry, memory controller circuitry, host controller circuitry, and host processor circuitry, among other examples. In some cases, a die 405 may be an example of or include a die 205. Although, the semiconductor component 400-a is shown as including four dies 405, the semiconductor component 400-a may include any quantity of dies 405.

As part of a manufacturing procedure, each of the dies 405 may be evaluated to verify proper operation. A manufacturing yield may refer to a quantity or proportion of dies 405 that satisfy evaluation (e.g., a quantity of “good” dies). For instance, an evaluation procedure may determine whether a die 405 includes a fault 415 (e.g., a defect, an error) that causes the die 405 to operate improperly. If a die 405 is found to include a fault 415, the die 405 may be rejected (e.g., discarded). A likelihood of rejection for relatively larger dies (e.g., the dies 405) may be higher than for relatively smaller dies. For instance, if a fault 415 is found in at least one portion of circuitry of the die 405, the entire die 405 may be rejected. Accordingly, a semiconductor component 400-a may be associated with a relatively low yield (e.g., because each of the dies 405 includes a fault 415).

To improve manufacturing yield of semiconductor components 400 (e.g., yield of wafers), it may be desirable to manufacture (e.g., fabricate) relatively smaller portions of a die 405 (e.g., smaller dies that are separable as individual portions of a die 405, separately manufacture various portions of circuitry of the die 405). For instance, a semiconductor component 400-b may include multiple dies 410 (e.g., chiplets, die portions), where a die 410 may be smaller than a die 405. Each die 410 may include a respective portion (e.g., a subset, less than all) of circuitry of a die 405, and may be relatively less complex than a die 405. Because the dies 410 may be individually separable, relatively smaller dies 410 may be rejected as opposed to rejection of an entire die 405 (e.g., a fault 415 may be isolated to relatively smaller portion of die), thus improving overall manufacturing yield (e.g., of known good dies 410). As an illustrative example, the semiconductor component 400-a and the semiconductor component 400-b may include faults 415 in multiple same portions of circuitry. The faults 415 in the semiconductor component 400-a may cause each of the dies 405 (e.g., the entire semiconductor component 400-a) to be rejected (e.g., even though the semiconductor component 400-a may include some good die portions). In contrast, the same faults 415 in the semiconductor component 400-b may cause only a portion of the dies 410 to be rejected (e.g., a die 410-a), while other dies may be accepted (e.g., a die 410-b). For instance, the die 410-b may be accepted (e.g., may be an example of a KGD) based on satisfying an evaluation procedure (e.g., evaluating circuitry or function thereof of the die 410-b).

In accordance with examples as described herein, and to improve manufacturing yield of semiconductor circuitry, a die assembly 450 having one or more semiconductor units 420 may be formed by interconnecting relatively smaller dies 410 (e.g., chiplets, logic chiplets, relatively smaller semiconductor dies) to otherwise support the functionality of relatively larger dies 405. For example, multiple dies 410 may be coupled with conductive lines 425 (e.g., via RDL) to form a semiconductor unit 420 (e.g., a unit having functionality of a dic 205, a die 405, or other dies). In some examples, each of the dies 410 may be fabricated from different wafers or from a same wafer. The semiconductor unit 420 may, in some examples, be functionally equivalent to a die 405. Gaps between the dies 410 may be filled with one or more dielectric materials 435 (e.g., a silicon oxide gap fill) that separate each of the dies 410 (e.g., separating substrates of the dies 410). In some examples, different dies 410 may use various manufacturing techniques (e.g., different techniques for transistor formation). For example, a first fabrication technique (e.g., memory manufacturing flow) may be used to fabricate transistors (e.g., FinFETs, planar transistors) of a die 410-c (e.g., for interface blocks 220) and a second fabrication technique (e.g., logic manufacturing flow, a foundry process) may be used to fabricate transistors (e.g., FinFETs, all-around gate transistors) of a die 410-d (e.g., for a host processor 210, for controllers 215). Additionally, different fabrication techniques may be associated with sourcing each die 410 from different wafers, from different manufacturers, or both. In some examples, multiple dies 410 together with the conductive lines 425, dielectric materials 435, and any other circuitry (e.g., TRVs) may be formed as part of a reconstructed KGD wafer (e.g., a wafer assembly of KGDs), which may be of various sizes (e.g., 200 millimeters, 300 millimeters, or some other size).

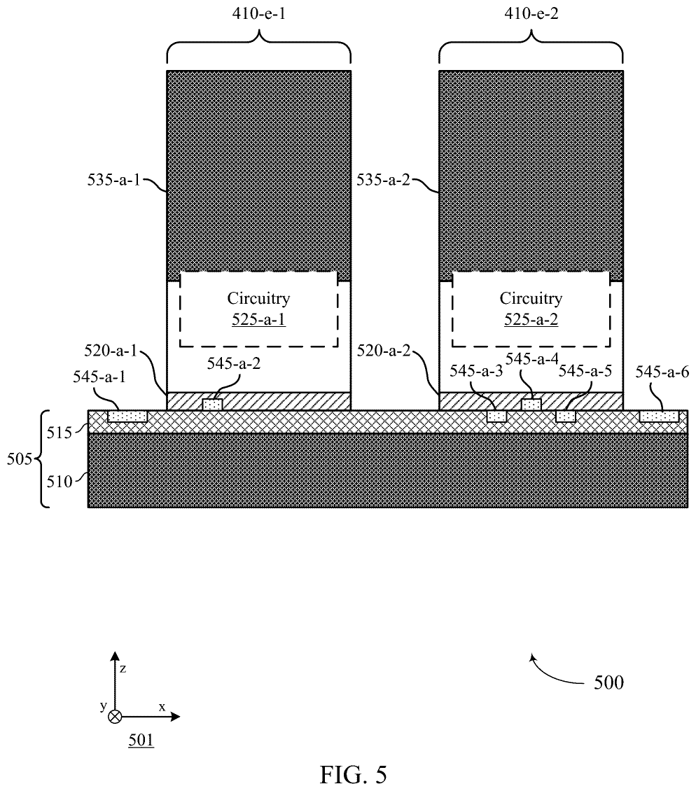

FIGS. 5 through 12 illustrate examples of operations for forming a semiconductor system 500 (e.g., a heterogeneous device, a semiconductor system of heterogeneous dies, a heterogeneous HBM system, a heterogeneous TCDRAM system) utilizing techniques for semiconductor die coupling in stacked memory architectures in accordance with examples as disclosed herein. For example, FIGS. 5 through 12 may illustrate aspects of a sequence of operations that may support manufacturing a system 100 or a portion thereof, a system 200 (e.g., a unit that supports the functionality of a die 205, a die 405), a die assembly 450, or some other device herein which may increase device yield during manufacturing and improve power delivery to stacked memory dies. Each of the figures may be described with reference to an x-direction, a y-direction, and a z-direction of the coordinate system 501. Operations illustrated in and described with reference to FIGS. 5 through 12 may be performed by a manufacturing system, such as a semiconductor fabrication system configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques.

FIG. 5 illustrates a portion of the semiconductor system 500 after a first set of one or more manufacturing operations. For example, the semiconductor system 500 may include a die 410-e-1 and a die 410-e-2 (e.g., KGDs, which may be heterogeneous KGDs), which may be bonded to a carrier 505.

A carrier 505 (e.g., a sacrificial silicon carrier) may include one or more material levels such as a substrate 510 (e.g., a carrier substrate, a wafer substrate) and a bonding layer 515. The carrier 505 may provide a surface for bonding (e.g., mounting) multiple dies 410-c and provide structural support for a semiconductor unit. Each die 410-e may include material levels such as a substrate 535 (e.g., a semiconductor substrate, crystalline substrate) and a bonding layer 520. Although, two dies 410-e are shown, any quantity of dies 410-e may be formed on a carrier 505 (e.g., arranged along the x-direction, arranged along the y-direction). The dies 410-e may each be an example of a die 410 (e.g., a semiconductor die, a chiplet, a portion of a semiconductor unit).

A bonding layer 515 may include one or more alignment features 545 (e.g., alignment markings, fiducial markings) such as alignment features 545-a-1, 545-a-3, 545-a-5, and 545-a-6. Alignment features 545 may include materials that are different from other materials of the bonding layer 515, which may provide visibility for proper alignment of or between the carrier 505 and one or more dies 410-e. In some examples, an alignment feature 545 may include a conductive material, which may also support an electrical coupling or may not support an electrical coupling (e.g., the alignment features 545-a-1 and 545-a-6 may support an electrical coupling, and the alignment features 545-a-2, 545-a-3, 545-a-4, and 545-a-5 may not).

The first set of manufacturing operations may include bonding semiconductor dies 410-e to the carrier 505 (e.g., as a chip-to-wafer bonding, as a face-to-face bonding). Each of the dies 410-e may include respective circuitry 525 that includes a portion of the circuitry associated with a semiconductor unit (e.g., respective portions of functionality associated with a die 205 or a die 405), which may have been evaluated for acceptable performance before the bonding of the first set of operations. In some examples, at least some instances of circuitry 525 may respectively include memory interface circuitry (e.g., interface blocks 220, interface blocks 245, logic blocks 225), memory controller circuitry (e.g., logic blocks 230, controllers 215), host controller circuitry, host processor circuitry (e.g., host processors 210), sensor circuitry (e.g., sensors 237, sensors 275), storage circuitry (e.g., memory arrays 250, non-volatile storage 235, non-volatile storage 270), other circuitry (e.g., graphics circuitry, peripheral circuitry), or any combination thereof. In some examples, circuitry 525 of one die 410 may be different than circuitry 525 of another die 410 (e.g., in a heterogeneous chiplet configuration) or may be the same circuitry. For example, the circuitry 525-a-1 may include memory interface circuitry and the circuitry 525-a-2 may include host processor circuitry, among other examples of differentiation among dies 410. In some examples, circuitry 525-a may include circuitry associated with one or more units 280-a-1 and may not include at least some of the circuitry associated with one or more units 280-a-2 (e.g., a host system 105 or a host processor 210 may be separately coupled, such as in an HBM implementation). In some other examples, circuitry 525-a may not include circuitry associated with the one or more units 280-a-1 (e.g., the one or more units 280-a-1 may be separately coupled) and may include circuitry associated with one or more units 280-a-2 (e.g., such as host processors 210 and controllers 215). In some examples, at least a portion of circuitry 525 (e.g., one or more transistors of the circuitry 525, complementary metal-oxide semiconductor (CMOS) circuitry) may be formed from a portion of a substrate 535 of a die 410-e (e.g., doped portions of a substrate 535, a doped semiconductor material, a doped crystalline semiconductor). In some examples, one or more instances of circuitry 525 may include front end of line (FEOL) circuitry (e.g., transistor circuitry), back end of line (BEOL) circuitry (e.g., interconnection circuitry, one or more conductive paths formed above transistor circuitry), or both.

Each die 410-e may include a bonding layer 520, which may be opposite a substrate 535 of the die 410-e (e.g., along the z-direction). The multiple dies 410-e may at least partially overlap along a direction from the carrier (e.g., along the z-direction, along a thickness dimension). Bonding a die 410-e may include bonding a face of the die 410-e that is opposite the substrate 535 of the die 410-e (e.g., a frontside of the die 410-e) to a face of the carrier 505 that is opposite the substrate 510 of the carrier 505 (e.g., a frontside of the carrier 505). A die 410-c and a carrier 505 may be bonded in accordance with a face-to-face bonding (e.g., a chip-to-wafer front-to-front fusion bonding), and the bonding may be a fusion bonding of one or more materials of a bonding layer 520-a with one or more materials of the bonding layer 515 of the carrier 505. In some examples, bonding of the multiple semiconductor dies 410-c to the carrier 505 may be based on alignment features 545 of the carrier 505, alignment features 545 of a die 410-e (e.g., included in the bonding layer 520-a, alignment feature 545-a-2, alignment feature 545-a-4), or both. In some examples, bonding of dies 410-e to a carrier 505 may provide a mechanical coupling between the dies 410 and the carrier 505 without an accompanying electrical coupling.

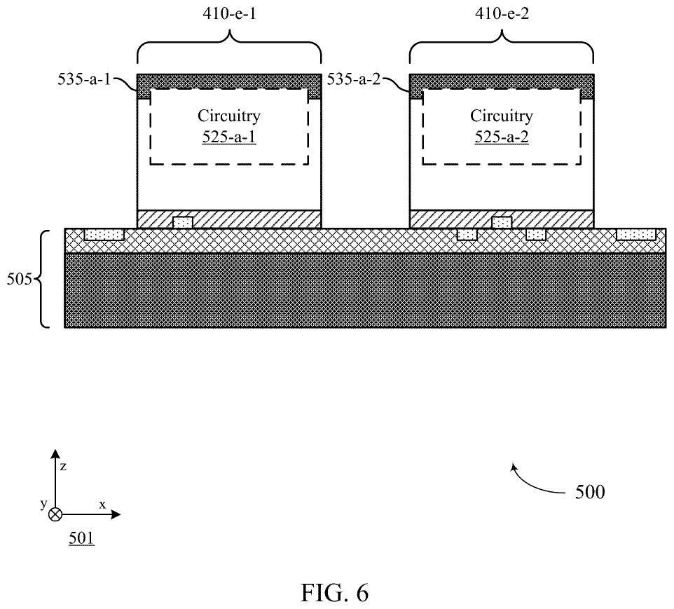

FIG. 6 illustrates a portion of the semiconductor system 500 after a second set of one or more manufacturing operations. For example, the second set of operations may include removing a portion of material from at least one die 410-c (e.g., the die 410-e-1, the die 410-e-2) after bonding the multiple dies 410-e to the carrier 505. For example, at least a portion of a substrate 535 of a die 410-e may be removed by chemical mechanical planarization (CMP) techniques, or other techniques such as thinning, grinding, cutting, polishing, planarization, or etching. Removing the portion of material (e.g., excess silicon, excess substrate 535) may reduce the size of the dies 410-e from a first thickness to a second thickness (e.g., in a silicon thinning operation, along the z-direction). In some examples, the second set of manufacturing operations may be optional and may not be performed as part of a manufacturing process (e.g., there may be no excess material that is to be removed from a die 410-c).

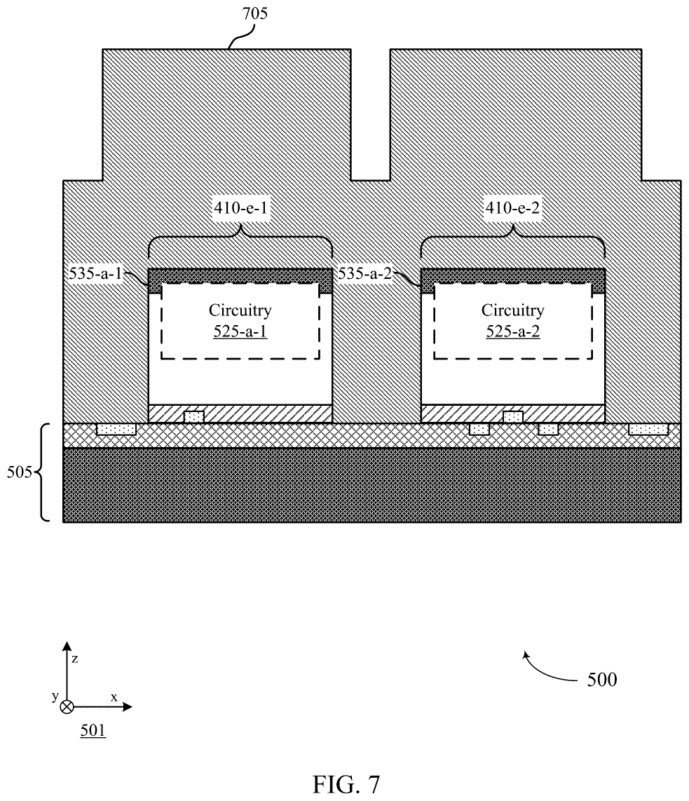

FIG. 7 illustrates a portion of the semiconductor system 500 after a third set of one or more manufacturing operations. For example, the third set of operations may include forming one or more dielectric materials 705 (e.g., silicon oxide, gap fill material, oxide, a nitride, a carbide, an oxide-nitride, an oxide-carbide, other conversion or doping of a substrate material, or some other dielectric material). In some examples, the one or more dielectric materials 705 may be formed at least along the carrier 505 between the multiple dies 410-c. The one or more dielectric materials 705 may separate respective substrates 535 of the dies 410-e (e.g., may separate each chiplet). For instance, the one or more dielectric materials 705 may separate a substrate 535-a-1 of a die 410-e-1 from a substrate 535-a-2 of a die 410-e-2. Accordingly, each of the dies 410-e may be electrically insulated from other dies 410-c by the one or more dielectric materials 705 (e.g., each die 410-e may be insulated by one or more dielectric materials 705 on each face other than a face that is bonded to the carrier 505), at least before subsequent interconnection operations. The one or more dielectric materials 705 may also provide structural support for various components of semiconductor system 500.

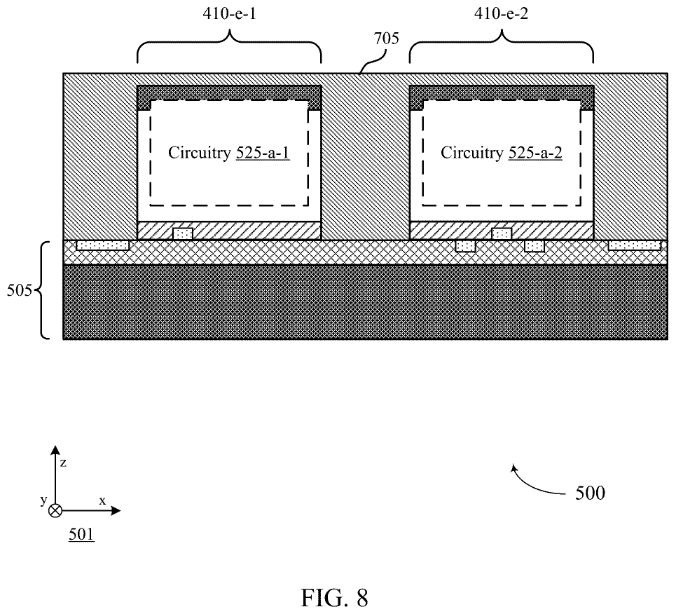

FIG. 8 illustrates a portion of the semiconductor system 500 after a fourth set of one or more manufacturing operations. For example, the fourth set of operations may include removing a portion of the one or more dielectric materials 705 (e.g., removing excess material, with at least some dielectric material remaining above the dies 410-e in some examples). For example, at least some of the one or more dielectric materials 705 above the dies 410-e (e.g., along the z-direction) may be removed after forming the one or more dielectric materials at least along the carrier 505. In some examples, removing the portion of the one or more dielectric materials 705 may involve a CMP (e.g., as a silicon oxide CMP).

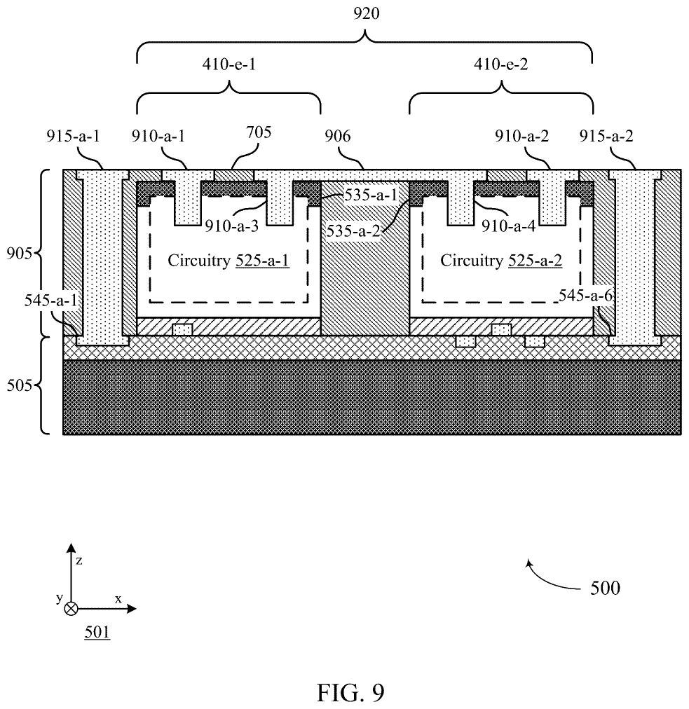

FIG. 9 illustrates a portion of the semiconductor system 500 after a fifth set of one or more manufacturing operations. For example, the fifth set of operations may include forming conductive paths 906 (e.g., forming at least a portion of an RDL, forming conductive signal paths, forming conductive paths 906 at least in part on a backside of the dies 410-c, conductive paths along various directions in an xy-plane), which may include forming one or more first cavities at a first depth (e.g., along the z-direction, from a surface of the one or more dielectric materials 705) through the one or more dielectric materials 705. In some examples, each of the conductive paths 906 may be in contact with (e.g., may provide an electrical coupling between) at least two dies 410-e (e.g., by way of via 910-a-3 and via 910-a-4).

The fifth set of operations may also include forming one or more vias 910 (e.g., TSVs, forming vias 910 on a backside of the dies 410-e, forming vias 910 through substrates 535), which may include forming one or more second cavities at a second depth through at least the one or more dielectric materials 705, where each second cavity may also be through at least a portion of a die 410-c (e.g., in contact with or exposing portions of circuitry 525-a). In some examples, one or more vias 910 may support an interface between a die 410-e and at least one of set of one or more other semiconductor dies (e.g., memory dies, stacks of dies 240), and may be TSVs based on being formed through at least a substrate 535. Additionally, or alternatively, one or more vias 910 may provide an interface between a die 410-c and at least one other die 410-c. For example, circuitry 525-a-1 of the die 410-e-1 and circuitry 525-a-2 of the 410-e-2 may be coupled (e.g., communicatively coupled, electrically coupled) based on via 910-a-3 through the substrate 535-a-1 and via 910-a-4 through the substrate 535-a-2, which may be coupled by one or more conductors of an RDL (e.g., conductive path 906).

The fifth set of operations may also include forming one or more vias 915 (e.g., TVs, PDN TRVs, bypassing vias), which may include forming one or more third cavities at a third depth through at least the one or more dielectric materials 705. Each third cavity may be formed between, beside, or otherwise bypass the multiple dies 410-e (e.g., along the x-direction, along the y-direction, or both) and may be in contact with the carrier 505 (e.g., may be filled with conductive material in contact with alignment features 545-a or otherwise contact or reach through the carrier 505). The vias 915 may be formed through a layer 905 (e.g., a logic layer, a layer including logic chiplets). The vias 915 may bypass the dies 410-c and may provide an interface between (e.g., may be later coupled with) a set of one or more other semiconductor dies (e.g., dies 240) located above the layer 905 and a surface of the one or more dielectric materials 705 opposite the set of one or more other semiconductor dies.

Forming the conductive paths 906, the vias 910, and the vias 915 may include concurrently or otherwise contiguously filling the one or more first cavities, the one or more second cavities, and the one or more third cavities with one or more conductive materials (e.g., in accordance with a concurrent damascene process, a triple damascene process, a backside triple damascene process). Thus, in some examples, the conductive paths 906, the vias 910, and the vias 915 may be referred to as or be included in a backside triple damascene RDL. Forming a semiconductor unit 920 may be based on filling the multiple conductive paths 906, the one or more vias 910, and, in some examples, the one or more vias 915, with one or more conductive materials (e.g., a single conductive material, a conductive liner material and a conductive fill material). For example, based on forming the conductive paths 906, each of the multiple dies 410-e may be electrically coupled (e.g., connected) with at least one other die 410-e (e.g., the die 410-e-1 may be electrically connected with the die 410-c-2) via an RDL (e.g., an RDL that may include multiple conductive paths 906). That is, electrically connecting the dies 410-e may be based on forming the RDL including the multiple conductive paths 906 over the dies 410-c. Forming the semiconductor unit 920 may be based on coupling each of the multiples dies 410-e with at least one other die 410-e. The semiconductor unit 920 may be an example of an implementation of the functionality of a die 205, a die 405, a logic die, or some other die.

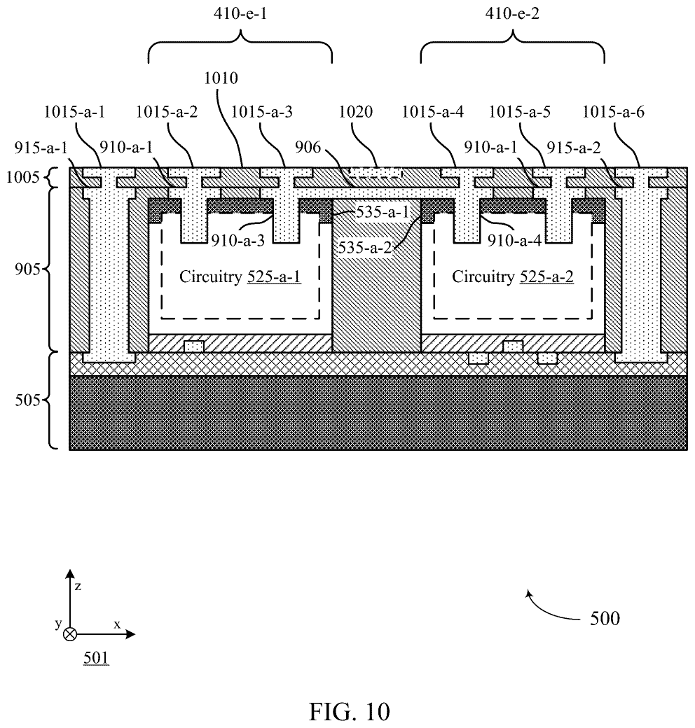

FIG. 10 illustrates a portion of a semiconductor system 500 after a sixth set of one or more manufacturing operations. For example, the sixth set of operations may include forming a layer 1005 (e.g., at least a portion of an RDL), which may include one or more dielectric materials 1010 and one or more conductive pads 1015 (e.g., bonding pads) over the dies 410-c. In some examples, the layer 1005 may also include conductive paths (e.g., signal paths of an RDL, along various directions in an xy-plane, not shown) between conductive pads 1015, or to provide electrical coupling between vias 910, vias 915, or a combination thereof. In some examples, each conductive pad 1015 may couple (e.g., or enable a coupling of) one or more other semiconductor dies (e.g., dies 240) stacked above the layer 1005 with a PDN (e.g., via the carrier 505, with a via 915, with a PDN TRV), with a via 910 of the dies 410-c, with an RDL (e.g., conductive paths 906) over the dies 410-e, or any combination thereof. The sixth set of manufacturing operations may also include forming one or more pads 1020 (e.g., redundant pads, dummy pads, conductive pads), which may be used for purposes other than electrical coupling of components (e.g., as an alignment feature). In some examples, at least some of the conductive pads 1015 may implement functionality of a contact 222. In some examples, forming the conductive pads 1015 and the pads 1020, along with corresponding vias (e.g., through the layer 1005, for coupling with the layer 905) and signal paths of the layer 1005, may be based on a concurrent filling of cavities with one or more conductive materials (e.g., in accordance with a concurrent damascene process, a double damascene process, a backside double damascene process). Thus, in some examples, the conductive pads 1015, the pads 1020, and the corresponding signal paths and vias of the layer 1005 may be referred to as or be included in a backside double damascene RDL, which may correspond to a backside double damascene process RDL that is formed over the triple damascene process RDL associated with the fifth set of operations (e.g., of a device of heterogeneous dies 410-c).

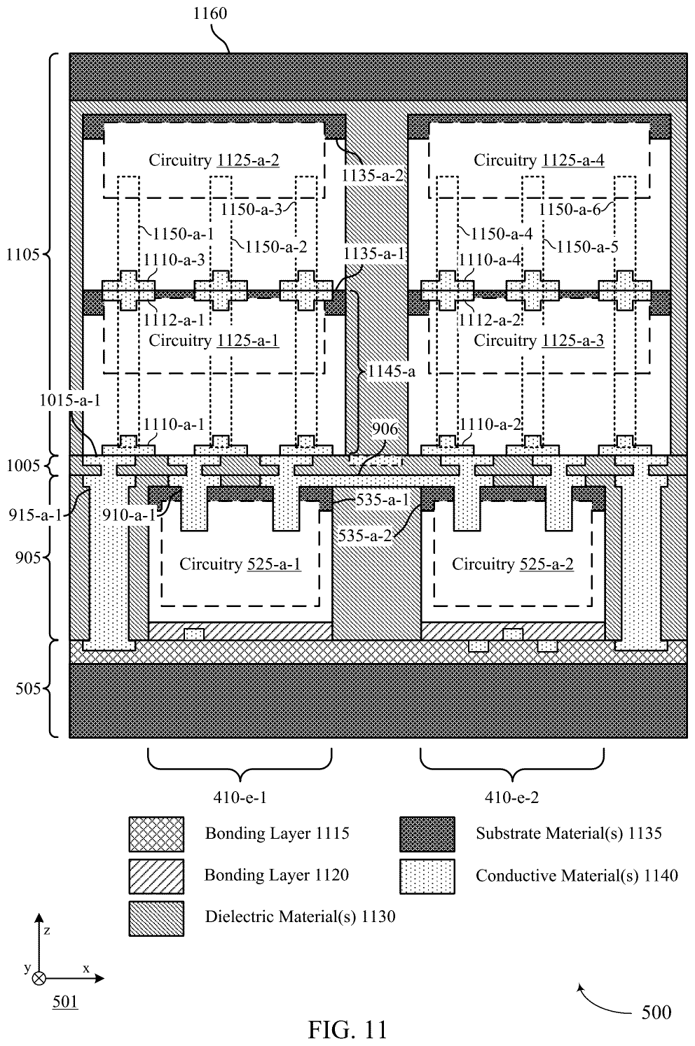

FIG. 11 illustrates a portion of a semiconductor system 500 after a seventh set of one or more manufacturing operations. For example, the seventh set of operations may include forming (e.g., stacking, assembling, bonding) a layer 1105 (e.g., including dies 240, memory dies, array dies) above the carrier 505, the layer 905, and the layer 1005. The components of the semiconductor system 500 may include various layers and materials such as a bonding layer 1115, a bonding layer 1120, one or more dielectric materials 1130 (e.g., silicon oxide), a substrate 1135 (e.g., silicon substrate), and one or more conductive materials 1140 (e.g., copper, aluminum, or some other material).

In some examples, forming the layer 1105 may include coupling (e.g., bonding) respective sets (e.g., stacks) of one or more dies 1145-a over (e.g., with) at least one of the dies 410-e (e.g., via one or more RDLs, via layer 1005), where each die of the respective set of dies 1145-a may include circuitry 1125-a such as a memory circuitry (e.g., a plurality of memory arrays, memory arrays 250), interface circuitry (e.g., interface blocks 245 or components thereof), or other circuitry (e.g., associated with non-volatile storage 270, sensors 275, or other circuitry). In some examples, the dies 1145 or stacks thereof may be separately coupled as respective sets onto at least one of the dies 410-e. In some other examples, multiple dies 1145 (e.g., of a layer of dies 1145) or stacks thereof may be contiguous (e.g., as part of a wafer or other semiconductor component, as part of a stack of wafers or other semiconductor components) or otherwise mechanically connected (e.g., along the x-direction, along the y-direction, not shown), which may include later separation (e.g., singulation) into semiconductor units. In some such other examples, the dies 1145 may be part of a reconstructed wafer or other reconstructed semiconductor component of dies 1145 (e.g., known-good dies 1145), for which such reconstruction may involve a coupling of singulated or otherwise separate dies 1145 with a carrier (e.g., similar to the coupling of dies 410 with the carrier 505, not shown). Thus, in some examples, a wafer of dies 1145, or a reconstructed wafer of dies 1145, may be coupled with (e.g., bonded to) semiconductor units 920 formed at least in part from coupled dies 410 (e.g., with an RDL providing at least a portion of such a coupling, such as an RDL between a reconstructed wafer of dies 1145 and a reconstructed wafer of dies 410).

The circuitry 1125-a may include FEOL circuitry (e.g., transistor circuitry, circuitry formed at least in part from doped portions of a substrate 1135) and BEOL circuitry (e.g., interconnection circuitry). Each instance of circuitry 1125-a may be operable based on an instance of the circuitry 525-a of a die 410-e to which the respective set is bonded and via one or more interconnection regions 1150-a. In some examples, interconnection regions 1150-a may include components or circuitry (e.g., TSVs, bonding pads, BEOL circuitry) that couples circuitry 1125 with other circuitry 1125 of respective dies 1145-a (e.g., coupling between circuitry 1125-a-1 and circuitry 1125-a-2), with conductive pads 1110, or with conductive pads 1112, or various combinations thereof.

In some examples, bonding one die 1145-a to another die 1145-a may involve bonding one or more conductive pads 1110-a with one or more conductive pads 1112-a. For example, a conductive pad 1110-a may be an implementation of a contact 247 or a contact 256, and a conductive pad 1112-a may be an implementation of a contact 257 or a contact 260, among other examples. In some examples, a conductive pad 1112-a of a first die 1145-a (e.g., conductive pad 1112-a-1) may be coupled with (e.g., fused with) a conductive pad 1110-a of a second die 1145-a (e.g., conductive pad 1110-a-3), including by way of a hybrid bonding implementation (e.g., a wafer-to-wafer or die-to-die front-to-back hybrid bonding). In some examples, such coupling may be accompanied by a coupling of respective dielectric portions (e.g., surface) of the dies 1145-a, such as a fusion of dielectric materials 242. In some examples, materials 1160 (e.g., additional silicon, additional substrate material) may be formed or placed on top of the semiconductor system 500 and may be bonded to a die 1145-a that is on top of a stack of dies 1145-a, including by way of a fusion bonding implementation (e.g., a wafer-to-wafer front-to-back fusion bonding).

In some examples, bonding a respective set of one or more dies 1145-a to a die 410-c may be based on one or more conductive pads 1110-a in each set of dies 1145-a and one or more conductive pads 1015-a in the dies 410-c. For example, a set of dies 1145-a may be bonded to a die 410-e by way of a hybrid bonding implementation (e.g., a stack-to-wafer front-to-back hybrid bonding). The interconnection regions 1150-a may be coupled with the conductive pads 1110-a to provide a communicative interface between dies 410-e and dies 1145-a. In some examples, an interconnection region 1150-a may implement functionality of a bus 255, 246, 251, 301, 302, 303, 304, or a combination thereof. For example, one or more conductive pads 1110-a (e.g., a conductive pad 1110-a-2) may be bonded with a via 910 (e.g., a TSV), one or more conductive paths 906 (e.g., an RDL), or both which may be through a substrate 535-a of the die 410-e to which the respective set of dies 1145-a is bonded. The vias 910 and the conductive paths 906 may provide an interface between the respective set of one or more dies 1145-a and the die 410-e. In some examples, one or more conductive pads 1110-a (e.g., conductive pad 1110-a-1) may be bonded with a via 915 (e.g., a PDN TRV) which may provide an interface through the layer 905 that bypasses the dies 410-c). In some examples, bonding the respective set of one or more dies 1145-a to the die 410-e may be based on a fusion between respective conductor portions and a fusion between respective dielectric portions (e.g., a surface-to-wafer bonding, a face-to-back bonding, a hybrid bonding of both dielectric materials and conductive materials). In some examples, at least some, if not all of the dies 410-e dies 1145-a may satisfy (e.g., may be verified to satisfy) an evaluation (e.g., an operational evaluation) prior to bonding the respective set of one or more dies 1145-a to the die 410-c.

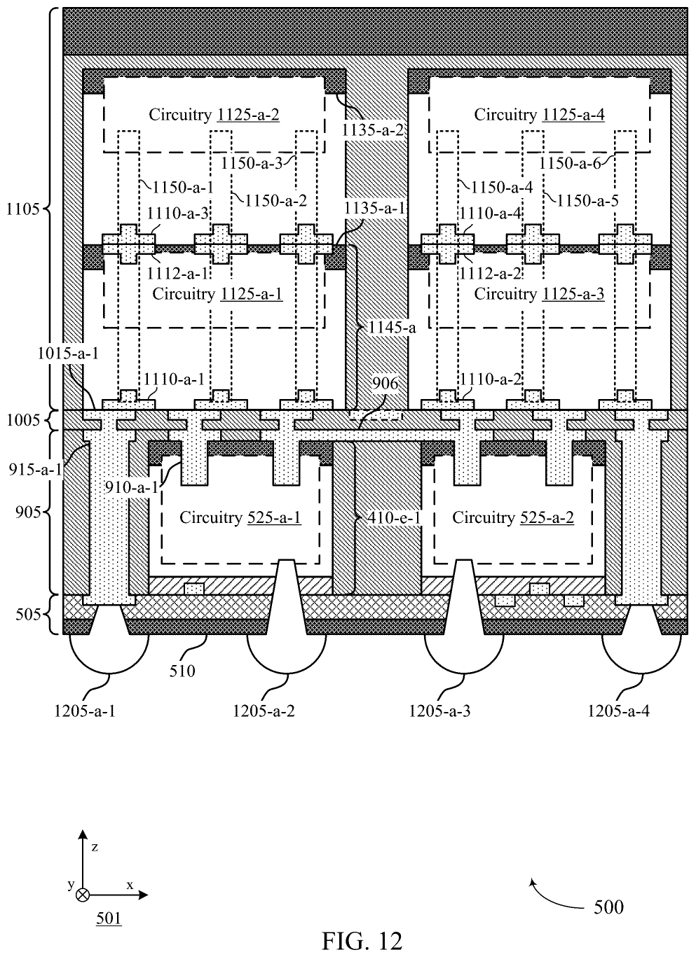

FIG. 12 illustrates a portion of a semiconductor system 500 after an eighth set of one or more manufacturing operations. For example, the eight set of operations may include forming one or more contacts 1205 (e.g., electrical contacts, solder balls, μ-bumps, controller collapse chip connect (C4) bumps) at one or more depths relative to the carrier 505 (e.g., along the z-direction). Forming the contacts 1205 may include forming cavities through at least a portion of carrier 505. In some examples, forming the one or more contacts 1205-a (e.g., for each of the dies 410-c) may be based on forming cavities through at least a portion of the carrier, through at least a portion of the dies 410-e, and forming one or more conductor materials in each of the cavities. Forming the contacts 1205 may include forming at least some contacts 1205 (e.g., contact 1205-a-2 and contact 1205-a-3) at a surface of the semiconductor system 500 (e.g., at the surface of the carrier 505 opposite the multiple dies 410-c) and coupled with circuitry 525 of a die 410-e. In some examples, one or more contacts 1205 (e.g., contact 1205-a-1 and contact 1205-a-4) may be formed at the surface of the semiconductor system 500 and coupled with the at least one set of one or more dies 1145-a, which may bypass the dies 410-e. For example, a via 915 may provide an interface between a set of dies 1145-a and a surface of a semiconductor unit (e.g., a surface of the layer 905) opposite a respective set of dies 1145-a via a contact 1205. In some examples, the semiconductor system 500 may include a combination of one or more first contacts 1205 (e.g., contact 1205-a-1) that may be coupled with one or more vias 915 (e.g., a PDN TRV) and one or more second contacts 1205 (e.g., contact 1205-a-2) that may be coupled with one or more dies 410-e (e.g., coupled with a pad of a logic chiplet), which may be associated with different depths along the z-direction. Based on forming the one or more contacts 1205, the semiconductor system 500 may be enabled to be communicatively couple with other components (e.g., a GPU or other peripheral component).

After the eighth set of manufacturing operations, the semiconductor system 500 may be ready for packaging, which may include separating (e.g., dicing) multiple semiconductor units 920 on the same carrier 505 from one another. In accordance with the techniques as described with reference to FIGS. 5 through 12, the semiconductor system 500 may include multiple dies 410-e (e.g., chiplets, logic chiplets, logic dies, semiconductor dies, die portions) that are electrically coupled via conductive paths 906 (e.g., included in an RDL) to form one or more semiconductor units 920 (e.g., associated with the functionality of a logic die, a die 205, or a die 405). The semiconductor system 500 may further include one or more set of dies 1145-a (e.g., dies 240, semiconductor dies, array dies, DRAM dies, stacks of memory dies), which may be bonded to respective dies 410-e (e.g., of respective semiconductor units 920) via one or more bonding pads 1015-a (e.g., in a layer 1005) and one or more vias 910 (e.g., TSVs). For example, a layer 905 (e.g., a lower die in a stack) may be associated with one or more units 280 and the layer 1105 may be associated with one or more dies 240. The one or more set of dies 1145-a may also be bonded to one or more vias 915 (e.g., PDN TRVs), which may provide an interface (e.g., a power delivery interface) to a set of dies 1145-a at a surface of the semiconductor system 500 (e.g., via a contact 1205-a).

Utilizing one or more techniques as described herein may support an increased manufacturing yield for wafers associated with components of semiconductor systems 500 (e.g., HBM devices, TCDRAM devices). For example, the techniques herein enable fabrication and evaluation of relatively smaller semiconductor dies (e.g., dies 410) that are individually separable and enable a reconstruction of relatively larger semiconductor units (e.g., implementing a functionality of a die 205 or a die 405) using multiple relatively smaller dies (e.g., using dies 410 that satisfy an evaluation). Additionally, the described techniques may enable direct power delivery to one or more stacked memory dies (e.g., dies 1145-a, dies 240) with decreased resistance based on the one or more vias 915, which may bypass the dies 410-e and support more efficient use of die area. Accordingly, manufacturing of semiconductor systems 500 may be associated with an increased yield and a semiconductor systems 500 may operate with increased efficiency. Although some of the described techniques are described in the context of memory systems, the techniques described herein may be implemented in other semiconductor systems that implement heterogencous semiconductor components (e.g., dies associated with different functions, including different logic functions, different storage or processing functions, or any combination thereof), including heterogeneous semiconductor components that are interconnected within a layer, between layers, or any combination thereof.

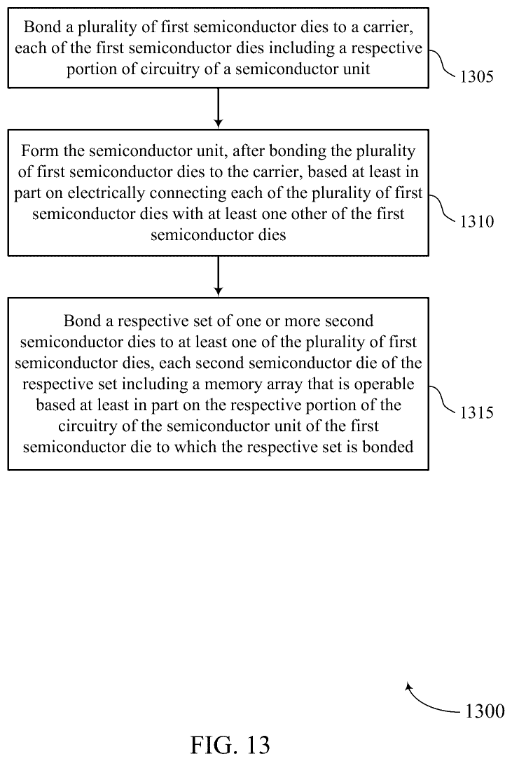

FIG. 13 shows a flowchart illustrating a method 1300 that supports techniques for semiconductor die coupling in stacked memory architectures in accordance with examples as disclosed herein. The operations of method 1300 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 1305, the method may include bonding a plurality of first semiconductor dies to a carrier, each of the first semiconductor dies including a respective portion of circuitry of a semiconductor unit.

At 1310, the method may include forming the semiconductor unit, after bonding the plurality of first semiconductor dies to the carrier, based at least in part on electrically connecting each of the plurality of first semiconductor dies with at least one other of the first semiconductor dies.

At 1315, the method may include bonding a respective set of one or more second semiconductor dies to at least one of the plurality of first semiconductor dies, each second semiconductor die of the respective set including a memory array that is operable based at least in part on the respective portion of the circuitry of the semiconductor unit of the first semiconductor die to which the respective set is bonded.

In some examples, an apparatus (e.g., a manufacturing system) as described herein may perform a method or methods, such as the method 1300. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for bonding a plurality of first semiconductor dies (e.g., dies 410) to a carrier (e.g., a carrier 505), each of the first semiconductor dies including a respective portion of circuitry (e.g., circuitry 525) of a semiconductor unit (e.g., a semiconductor unit 920); forming the semiconductor unit, after bonding the plurality of first semiconductor dies to the carrier, based at least in part on electrically connecting each of the plurality of first semiconductor dies with at least one other of the first semiconductor dies; and bonding a respective set of one or more second semiconductor dies (e.g., dies 240, dies 1145) to at least one of the plurality of first semiconductor dies, each second semiconductor die of the respective set including a memory array (e.g., at least one memory array 250, of circuitry 1125) that is operable based at least in part on the respective portion of the circuitry of the semiconductor unit of the first semiconductor die to which the respective set is bonded.

Aspect 2: The method or apparatus of aspect 1, where, for each of the first semiconductor dies, the respective portion of circuitry includes memory interface circuitry, memory controller circuitry, host controller circuitry, host processor circuitry, or any combination thereof.

Aspect 3: The method or apparatus of any of aspects 1 through 2, where a first respective portion of circuitry of a first semiconductor die of the semiconductor unit is associated with a first logic function and a second respective portion of circuitry of a different first semiconductor die of the semiconductor unit is associated with a second logic function different than the first logic function.

Aspect 4: The method or apparatus of any of aspects 1 through 3, where a first respective set of one or more second semiconductor dies and a second respective set of one or more second semiconductor dies are included in a reconstructed wafer of second semiconductor dies that is bonded to the semiconductor unit.

Aspect 5: The method or apparatus of any of aspects 1 through 4, further including operations, features, circuitry, logic, means, or instructions, or any combination thereof for forming one or more dielectric materials (e.g., dielectric materials 705) at least along the carrier between the plurality of first semiconductor dies, where the one or more dielectric materials separate respective substrates of the first semiconductor dies (e.g., substrates 535).

Aspect 6: The method or apparatus of aspect 5, further including operations, features, circuitry, logic, means, or instructions, or any combination thereof for forming a plurality of first cavities at a first depth through the one or more dielectric materials, each of the first cavities in contact with at least two of the first semiconductor dies; forming a plurality of second cavities at a second depth through the one or more dielectric materials, each of the second cavities through at least a portion of a respective one of the first semiconductor dies; forming a plurality of third cavities at a third depth through the one or more dielectric materials, each of the third cavities between the plurality of first semiconductor dies and in contact with the carrier; and forming one or more conductor materials concurrently (e.g., contiguously) in the plurality of first cavities, in the plurality of second cavities, and in the plurality of third cavities.

Aspect 7: The method or apparatus of aspect 6, further including operations, features, circuitry, logic, means, or instructions, or any combination thereof for forming one or more conductive pads (e.g., bonding pads 1015, pads 1020), one or more conductive paths, and one or more vias in one or more second dielectric materials (e.g., layer 1005) adjacent to the one or more conductor materials (e.g., conductive paths 906), wherein the one or more conductive pads, the one or more conductive paths, and the one or more vias are formed based at least in part on forming one or more second conductor materials concurrently in cavities associated the one or more conductive pads, the one or more conductive paths, and the one or more vias.

Aspect 8: The method or apparatus of any of aspects 1 through 7, further including operations, features, circuitry, logic, means, or instructions, or any combination thereof for removing a portion of the one or more dielectric materials above the plurality of first semiconductor dies after forming the one or more dielectric materials at least along the carrier.

Aspect 9: The method or apparatus of any of aspects 1 through 8, further including operations, features, circuitry, logic, means, or instructions, or any combination thereof for forming one or more vias (e.g., vias 915) through one or more dielectric materials between the plurality of first semiconductor dies, each of the one or more vias coupled with one of the sets of one or more second semiconductor dies.

Aspect 10: The method or apparatus of aspect 9, where at least one of the one or more vias provides (e.g., supports, is part of) an interface between the respective set of one or more second semiconductor dies and a surface of the semiconductor unit opposite the respective set of one or more second semiconductor dies.

Aspect 11: The method or apparatus of any of aspects 9 through 10, further including operations, features, circuitry, logic, means, or instructions for forming one or more electrical contacts for each of the one or more vias based at least in part on forming cavities through at least a portion of the carrier and forming one or more conductor materials in the cavities.

Aspect 12: The method or apparatus of any of aspects 1 through 11, where electrically connecting each of the plurality of first semiconductor dies is based at least in part on forming a plurality of conductive signal paths (e.g., conductive paths 906) over the first semiconductor dies of the semiconductor unit.

Aspect 13: The method or apparatus of aspect 12, further including operations, features, circuitry, logic, means, or instructions, or any combination thereof for verifying that each first semiconductor die of the plurality of first semiconductor dies and the respective set of one or more second semiconductor dies satisfy an operational evaluation prior to bonding the respective set of one or more second semiconductor dies to the at least one of the plurality of first semiconductor dies.

Aspect 14: The method or apparatus of any of aspects 1 through 13, where bonding the respective set of one or more second semiconductor dies to the at least one of the plurality of first semiconductor dies is based at least in part on forming one or more vias (e.g., vias 910) through a substrate of the first semiconductor die to which the respective set is bonded.

Aspect 15: The method or apparatus of aspect 14, where each via provides an interface between the respective set of one or more second semiconductor dies and the at least one first semiconductor die, an interface between the at least one first semiconductor die and at least one other first semiconductor die, or both.

Aspect 16: The method or apparatus of any of aspects 1 through 15, further including operations, features, circuitry, logic, means, or instructions, or any combination thereof for forming a plurality of conductive pads (e.g., conductive pads 1015) over the plurality of first semiconductor dies, where each of the plurality of conductive pads couples the respective set of one or more second semiconductor dies with a PDN via the carrier, with a TSV of the plurality of first semiconductor dies, with an RDL over the plurality of first semiconductor dies, or any combination thereof.

Aspect 17: The method or apparatus of any of aspects 1 through 16, where bonding the respective set of one or more second semiconductor dies to the at least one of the plurality of first semiconductor dies is based at least in part on a fusion between respective conductor portions and a fusion between respective dielectric portions.

Aspect 18: The method or apparatus of any of aspects 1 through 17, further including operations, features, circuitry, logic, means, or instructions, or any combination thereof for forming one or more electrical contacts for each of the first semiconductor dies based at least in part on forming cavities through at least a portion of the carrier and forming one or more conductor materials in the cavities.

Aspect 19: The method or apparatus of any of aspects 1 through 18, where bonding the plurality of first semiconductor dies to the carrier includes, for at least one first semiconductor die, bonding a face of the at least one semiconductor die that is opposite a substrate of the at least one semiconductor die to the carrier.

Aspect 20: The method or apparatus of any of aspects 1 through 19, further including operations, features, circuitry, logic, means, or instructions, or any combination thereof for removing a portion of material from at least one of the first semiconductor dies after bonding the plurality of first semiconductor dies to the carrier.

Aspect 21: The method or apparatus of any of aspects 1 through 20, where the plurality of first semiconductor dies are at least partially overlapping along a direction from the carrier.

Aspect 22: The method or apparatus of any of aspects 1 through 21, where the bonding of the plurality of first semiconductor dies to the carrier is based at least in part on one or more alignment features (e.g., alignment features 545) of the carrier.

Aspect 23: The method or apparatus of any of aspects 1 through 22, where the bonding of the plurality of first semiconductor dies to the carrier provides a mechanical coupling between the plurality of first semiconductor dies to the carrier without an accompanying electrical coupling.

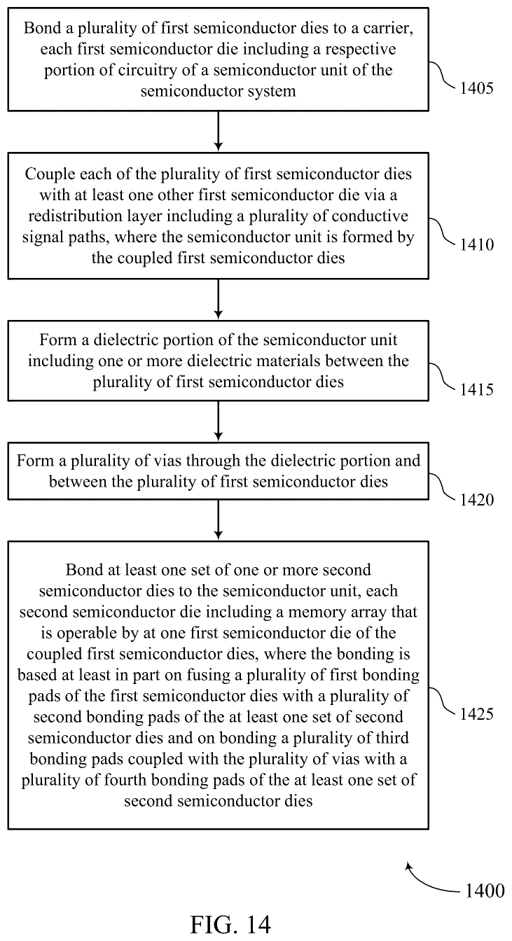

FIG. 14 shows a flowchart illustrating a method 1400 that supports techniques for semiconductor die coupling in stacked memory architectures in accordance with examples as disclosed herein. The operations of method 1400 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 1405, the method may include bonding a plurality of first semiconductor dies to a carrier, each first semiconductor die including a respective portion of circuitry of a semiconductor unit of the semiconductor system.

At 1410, the method may include coupling each of the plurality of first semiconductor dies with at least one other first semiconductor die via an RDL including a plurality of conductive signal paths, where the semiconductor unit is formed by the coupled first semiconductor dies.

At 1415, the method may include forming a dielectric portion of the semiconductor unit including one or more dielectric materials between the plurality of first semiconductor dies.

At 1420, the method may include forming a plurality of vias through the dielectric portion and between the plurality of first semiconductor dies.

At 1425, the method may include bonding at least one set of one or more second semiconductor dies to the semiconductor unit, each second semiconductor die including a memory array that is operable by at one first semiconductor die of the coupled first semiconductor dies, where the bonding is based at least in part on fusing a plurality of first bonding pads of the first semiconductor dies with a plurality of second bonding pads of the at least one set of second semiconductor dies and on bonding a plurality of third bonding pads coupled with the plurality of vias with a plurality of fourth bonding pads of the at least one set of second semiconductor dies.

In some examples, an apparatus (e.g., a manufacturing system) as described herein may perform a method or methods, such as the method 1400. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 24: A method or apparatus including operations, features, circuitry, logic, means, or instructions, or any combination thereof for bonding a plurality of first semiconductor dies to a carrier, each first semiconductor die including a respective portion of circuitry of a semiconductor unit of the semiconductor system; coupling each of the plurality of first semiconductor dies with at least one other first semiconductor die via an RDL including a plurality of conductive signal paths, where the semiconductor unit is formed by the coupled first semiconductor dies; forming a dielectric portion of the semiconductor unit including one or more dielectric materials between the plurality of first semiconductor dies; forming a plurality of vias through the dielectric portion and between the plurality of first semiconductor dies; and bonding at least one set of one or more second semiconductor dies to the semiconductor unit, each second semiconductor die including a memory array that is operable by at one first semiconductor die of the coupled first semiconductor dies, where the bonding is based at least in part on fusing a plurality of first bonding pads of the first semiconductor dies with a plurality of second bonding pads of the at least one set of second semiconductor dies and on bonding a plurality of third bonding pads coupled with the plurality of vias with a plurality of fourth bonding pads of the at least one set of second semiconductor dies.

It should be noted that the methods described herein describe possible implementations, and that the operations and the steps may be rearranged or otherwise modified and that other implementations are possible. Further, portions from two or more of the methods may be combined.

An system is described. The following provides an overview of aspects of the system as described herein:

Aspect 25: A system, including: a carrier including one or more material levels; a plurality of first semiconductor dies bonded with the carrier, each first semiconductor die including a respective substrate that is separate from the respective substrate of each other first semiconductor die, and each first semiconductor dies including a respective portion of circuitry of a semiconductor unit that is electrically coupled with the respective portion of circuitry of the semiconductor unit of at least one other first semiconductor die; and at least one set of one or more second semiconductor dies, each set of one or more second semiconductor dies electrically coupled with a respective first semiconductor die of the plurality of first semiconductor dies, and each second semiconductor die including one or more memory arrays operable based at least in part on the respective first semiconductor die to which the second semiconductor die is connected.

Aspect 26: The system of aspect 25, where, for each of the first semiconductor dies, the respective portion of circuitry includes memory interface circuitry, memory controller circuitry, host controller circuitry, host processor circuitry, or any combination thereof.

Aspect 27: The system of any of aspects 25 through 26, further including: a dielectric portion of one or more dielectric materials between the respective substrates of the plurality of first semiconductor dies.

Aspect 28: The system of aspect 27, further including: one or more vias through the dielectric portion between the plurality of first semiconductor dies, each of the one or more vias coupled with one of the sets of one or more second semiconductor dies and bypassing the plurality of first semiconductor dies.

Aspect 29: The system of aspect 28, where at least one of the one or more vias provides an interface between the one of the sets of one or more second semiconductor dies and a surface of the semiconductor unit opposite the respective set of one or more second semiconductor dies.

Aspect 30: The system of any of aspects 25 through 29, further including: an RDL including a plurality of conductive signal paths, where each first semiconductor die is electrically coupled with the at least one other first semiconductor die via the RDL.

Aspect 31: The system of any of aspects 25 through 30, further including: one or more vias formed through the respective substrate of at least one of the plurality of first semiconductor dies, where each via provides an interface between at least one of the sets of one or more second semiconductor dies and the respective first semiconductor die, an interface between the at least one first semiconductor die and at least one other first semiconductor die, or both.

Aspect 32: The system of any of aspects 25 through 31, further including: a plurality of conductive pads over the plurality of first semiconductor dies, where each of the plurality of conductive pads couples the respective set of one or more second semiconductor dies with a PDN via the carrier, with a TSV of the plurality of first semiconductor dies, with an RDL over the plurality of first semiconductor dies, or any combination thereof.

Aspect 33: The system of any of aspects 25 through 32, further including: one or more first electrical contacts at a surface of the system and coupled with at least one first semiconductor die of the plurality of first semiconductor dies; and one or more second electrical contacts at the surface of the system and coupled with the at least one set of one or more second semiconductor dies and bypassing the plurality of first semiconductor dies.

An system is described. The following provides an overview of aspects of the system as described herein:

Aspect 34: A system formed by a process of: bonding a plurality of first semiconductor dies to a carrier, each of the first semiconductor dies including a respective portion of circuitry of a semiconductor unit; forming the semiconductor unit, after bonding the plurality of first semiconductor dies to the carrier, based at least in part on electrically connecting each of the plurality of first semiconductor dies with at least one other of the first semiconductor dies; and bonding a respective set of one or more second semiconductor dies to at least one of the plurality of first semiconductor dies, each second semiconductor die of the respective set including a memory array that is operable based at least in part on the respective portion of the circuitry of the semiconductor unit of the first semiconductor die to which the respective set is bonded.

An system is described. The following provides an overview of aspects of the system as described herein:

Aspect 35: A system, including: a plurality of first semiconductor dies that are electrically coupled to form a semiconductor unit of the system; a dielectric material separating respective substrates associated with each of the plurality of first semiconductor dies; an RDL including a plurality of conductive paths, the plurality of conductive paths electrically connecting each of the plurality of first semiconductor dies with at least one other first semiconductor die; one or more sets of second semiconductor dies, each second semiconductor die including a plurality of memory arrays; one or more bonding pads coupling each set of second semiconductor dies with a respective one of the plurality of first semiconductor dies; and a plurality of vias through the dielectric material and between the plurality of first semiconductor dies, each of the plurality of vias coupled with at least one set of second semiconductor dies.

Aspect 36: The system of aspect 35, further including: a first portion comprising one or more first conductor materials contiguously formed along three depths relative to a thickness of the system; and a second portion over the first portion, the second portion comprising one or more second conductor materials contiguously formed along two depths relative to the thickness of the system.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. At any given time, a conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processor. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a computer, or a processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
bonding a plurality of first semiconductor dies to a carrier, each of the first semiconductor dies comprising a respective portion of circuitry of a semiconductor unit;
forming the semiconductor unit, after bonding the plurality of first semiconductor dies to the carrier, based at least in part on electrically connecting each of the plurality of first semiconductor dies with at least one other of the first semiconductor dies; and
bonding a respective set of one or more second semiconductor dies to at least one of the plurality of first semiconductor dies, each second semiconductor die of the respective set comprising a memory array that is operable based at least in part on the respective portion of the circuitry of the semiconductor unit of the first semiconductor die to which the respective set is bonded.

2. The method of claim 1, wherein, for each of the first semiconductor dies, the respective portion of circuitry comprises memory interface circuitry, memory controller circuitry, host controller circuitry, host processor circuitry, or any combination thereof.

3. The method of claim 1, wherein a first respective portion of circuitry of a first semiconductor die of the semiconductor unit is associated with a first logic function and a second respective portion of circuitry of a different first semiconductor die of the semiconductor unit is associated with a second logic function different than the first logic function.

4. The method of claim 1, wherein a first respective set of one or more second semiconductor dies and a second respective set of one or more second semiconductor dies are included in a reconstructed wafer of second semiconductor dies that is bonded to the semiconductor unit.

5. The method of claim 1, further comprising:
forming one or more dielectric materials at least along the carrier between the plurality of first semiconductor dies, wherein the one or more dielectric materials separate respective substrates of the first semiconductor dies.

6. The method of claim 5, further comprising:
forming a plurality of first cavities at a first depth through the one or more dielectric materials, each of the first cavities in contact with at least two of the first semiconductor dies;
forming a plurality of second cavities at a second depth through the one or more dielectric materials, each of the second cavities through at least a portion of a respective one of the first semiconductor dies;
forming a plurality of third cavities at a third depth through the one or more dielectric materials, each of the third cavities between the plurality of first semiconductor dies and in contact with the carrier; and
forming one or more conductor materials concurrently in the plurality of first cavities, in the plurality of second cavities, and in the plurality of third cavities.

7. The method of claim 6, further comprising:
forming one or more conductive pads, one or more conductive paths, and one or more vias in one or more second dielectric materials adjacent to the one or more conductor materials, wherein the one or more conductive pads, the one or more conductive paths, and the one or more vias are formed based at least in part on forming one or more second conductor materials concurrently in cavities associated the one or more conductive pads, the one or more conductive paths, and the one or more vias.

8. The method of claim 1, further comprising:
forming one or more vias through one or more dielectric materials between the plurality of first semiconductor dies, each of the one or more vias coupled with one of the sets of one or more second semiconductor dies.

9. The method of claim 8, wherein at least one of the one or more vias provides an interface between the respective set of one or more second semiconductor dies and a surface of the semiconductor unit opposite the respective set of one or more second semiconductor dies.

10. The method of claim 8, further comprising:
forming one or more electrical contacts for each of the one or more vias based at least in part on forming cavities through at least a portion of the carrier and forming one or more conductor materials in the cavities.

11. The method of claim 1, wherein electrically connecting each of the plurality of first semiconductor dies is based at least in part on forming a plurality of conductive signal paths over the first semiconductor dies of the semiconductor unit.

12. The method of claim 11, further comprising:
verifying that each first semiconductor die of the plurality of first semiconductor dies and the respective set of one or more second semiconductor dies satisfy an operational evaluation prior to bonding the respective set of one or more second semiconductor dies to the at least one of the plurality of first semiconductor dies.

13. The method of claim 1, wherein bonding the respective set of one or more second semiconductor dies to the at least one of the plurality of first semiconductor dies is based at least in part on forming one or more vias through a substrate of the first semiconductor die to which the respective set is bonded.

14. The method of claim 1, further comprising:
forming one or more electrical contacts for each of the first semiconductor dies based at least in part on forming cavities through at least a portion of the carrier and forming one or more conductor materials in the cavities.

15. The method of claim 1, wherein bonding the plurality of first semiconductor dies to the carrier comprises, for at least one first semiconductor die, bonding a face of the at least one semiconductor die that is opposite a substrate of the at least one semiconductor die to the carrier.

16. A system, comprising:
a carrier comprising one or more material levels;
a plurality of first semiconductor dies bonded with the carrier, each first semiconductor die comprising a respective substrate that is separate from the respective substrate of each other first semiconductor die, and each first semiconductor dies comprising a respective portion of circuitry of a semiconductor unit that is electrically coupled with the respective portion of circuitry of the semiconductor unit of at least one other first semiconductor die; and
at least one set of one or more second semiconductor dies, each set of one or more second semiconductor dies electrically coupled with a respective first semiconductor die of the plurality of first semiconductor dies, and each second semiconductor die comprising one or more memory arrays operable based at least in part on the respective first semiconductor die to which the second semiconductor die is connected.

17. The system of claim 16, wherein for each of the first semiconductor dies, the respective portion of circuitry comprises memory interface circuitry, memory controller circuitry, host controller circuitry, host processor circuitry, or any combination thereof.

18. The system of claim 16, further comprising:
a dielectric portion of one or more dielectric materials between the respective substrates of the plurality of first semiconductor dies.

19. The system of claim 18, further comprising:
one or more vias through the dielectric portion between the plurality of first semiconductor dies, each of the one or more vias coupled with one of the sets of one or more second semiconductor dies and bypassing the plurality of first semiconductor dies.

20. The system of claim 19, wherein at least one of the one or more vias provides an interface between the one of the sets of one or more second semiconductor dies and a surface of the semiconductor unit opposite the respective set of one or more second semiconductor dies.

21. The system of claim 16, further comprising:
a redistribution layer comprising a plurality of conductive signal paths, wherein each first semiconductor die is electrically coupled with the at least one other first semiconductor die via the redistribution layer.

22. The system of claim 16, further comprising:
one or more vias formed through the respective substrate of at least one of the plurality of first semiconductor dies, wherein each via provides an interface between at least one of the sets of one or more second semiconductor dies and the respective first semiconductor die, an interface between the at least one first semiconductor die and at least one other first semiconductor die, or both.

23. The system of claim 16, further comprising:
a plurality of conductive pads over the plurality of first semiconductor dies, wherein each of the plurality of conductive pads couples the respective set of one or more second semiconductor dies with a power distribution network via the carrier, with a through silicon via of the plurality of first semiconductor dies, with a redistribution layer over the plurality of first semiconductor dies, or any combination thereof.

24. The system of claim 16, further comprising:
one or more first electrical contacts at a surface of the system and coupled with at least one first semiconductor die of the plurality of first semiconductor dies; and
one or more second electrical contacts at the surface of the system and coupled with the at least one set of one or more second semiconductor dies and bypassing the plurality of first semiconductor dies.

25. A system, comprising:
a plurality of first semiconductor dies that are electrically coupled to form a semiconductor unit of the system;
a dielectric material separating respective substrates associated with each of the plurality of first semiconductor dies;
a redistribution layer comprising a plurality of conductive paths, the plurality of conductive paths electrically connecting each of the plurality of first semiconductor dies with at least one other first semiconductor die;
one or more sets of second semiconductor dies, each second semiconductor die comprising a plurality of memory arrays;
one or more bonding pads coupling each set of second semiconductor dies with a respective one of the plurality of first semiconductor dies; and
a plurality of vias through the dielectric material and between the plurality of first semiconductor dies, each of the plurality of vias coupled with at least one set of second semiconductor dies.

26. The system of claim 25, wherein the redistribution layer comprises:
a first portion comprising one or more first conductor materials contiguously formed along three depths relative to a thickness of the system; and
a second portion over the first portion, the second portion comprising one or more second conductor materials contiguously formed along two depths relative to the thickness of the system.
